(19) United States
(12) Patent Application Publication
(10) Pub. No.: US 2010/0000606 A1
(43) Pub. Date: Jan. 7, 2010

(54) ORGANIC PHOTOSENSITIVE DEVICES

(76) Inventors: Mark E. Thompson, Anaheim, CA (US); Peter Djurovich, Los Angeles, CA (US)

Correspondence Address: DUANE MORRIS LLP - NY;PATENT DEPARTMENT, 1540 BROADWAY, NEW YORK, NY, 10036-4086, US

(21) Appl. No.: 12/355,475

(22) Filed: May 11, 2009

Related U.S. Application Data
(63) Continuation of application No. 10/809,979, filed on Mar. 26, 2004, now abandoned.

(51) Int. Cl. H01L 51/46

(52) U.S. Cl. 136/263; 257/40; 257/E51.013; 257/E51.026

(57) ABSTRACT

The present invention generally relates to organic photosensitive optoelectronic devices. More specifically, it is directed to organic photovoltaic devices, e.g., organic solar cells. More specifically, it is directed to organic photosensitive optoelectronic devices that comprise a cyclometallated organometallic compound as a light absorbing material.

### FIELD OF THE INVENTION

The present invention generally relates to organic photosensitive optoelectronic devices. More specifically, it is directed to organic photosensitive optoelectronic devices that comprise an organometallic compound as a light absorbing material.

### BACKGROUND OF THE INVENTION

Optoelectronic devices rely on the optical and electronic properties of materials to either produce or detect electromagnetic radiation electronically or to generate electricity from ambient electromagnetic radiation. Photosensitive optoelectronic devices convert electromagnetic radiation into electricity. Photovoltaic (PV) devices or Solar cells, which are a type of photosensitive optoelectronic device, are specifically used to generate an electrical power. PV devices, which may generate electrical power from light sources other than sunlight, are used to drive power consuming loads to provide, for example, lighting, heating, or to operate electronic equipment such as computers or remote monitoring or communications equipment. These power generation applications also often involve the charging of batteries or other energy storage devices so that equipment operation may continue when direct illumination from the sun or other ambient light sources is not available. As used herein the term “resistive load” refers to any power consuming or storing device, equipment or system. Another type of photosensitive optoelectronic device is a photoconductor cell. In this function, signal detection circuitry monitors the resistance of the device to detect changes due to the absorption of light. Another type of photosensitive optoelectronic device is a photodetector. In operation a photodetector has a voltage applied and a current detecting circuit measures the current generated when the photodetector is exposed to electromagnetic radiation. A detecting circuit as described herein is capable of providing a bias voltage to a photodetector and measuring the electronic response of the photodetector to ambient electromagnetic radiation. These three classes of photosensitive optoelectronic devices may be characterized according to whether a rectifying junction as defined below is present and also according to whether the device is operated with an external applied voltage, also known as a bias or bias voltage. A photoconductor cell does not have a rectifying junction and is normally operated with a bias. A PV device has at least one rectifying junction and is operated with no external bias. A photodetector has at least one rectifying junction and is usually but not always operated with a bias.

Traditionally, photosensitive optoelectronic devices have been constructed of a number of inorganic semiconductors, e.g., crystalline, polycrystalline and amorphous silicon, gallium arsenide, cadmium telluride and others. Herein the term “semiconductor” denotes materials which can conduct electricity when charge carriers are induced by thermal or electromagnetic excitation. The term “photoconductive” generally relates to the process in which electromagnetic radiant energy is absorbed and thereby converted to excitation energy of electric charge carriers so that the carriers can conduct, i.e., transport, electric charge in a material. The terms “photoconductor” and “photoconductive material” are used herein to refer to semiconductor materials which are chosen for their property of absorbing electromagnetic radiation to generate electric charge carriers.

Solar cells may be characterized by the efficiency with which they can convert incident solar power to useful electric power. Devices utilizing crystalline or amorphous silicon dominate commercial applications, and some have achieved efficiencies of 23% or greater. However, efficient crystalline-based devices, especially of large surface area, are difficult and expensive to produce due to the problems inherent in producing large crystals without significant efficiency-degrading defects. On the other hand, high efficiency amorphous silicon devices still suffer from problems with stability. Present commercially available amorphous silicon cells have stabilized efficiencies between 4 and 8%. More recent efforts have focused on the use of organic photovoltaic cells to achieve acceptable photovoltaic conversion efficiencies with economical production costs.

Solar cells are optimized for maximum electrical power generation under standard illumination conditions (i.e., AM1.5 spectral illumination), for the maximum product of photocurrent times photovoltage. The power conversion efficiency of such a cell under standard illumination conditions depends on the following three parameters: (1) the current density under zero bias, i.e., the short-circuit current density I_{SC}, (2) the photovoltage under open circuit conditions, i.e., the open circuit voltage V_{OC}, and (3) the fill factor, ff.

PV devices produce a photo-generated current when they are connected across a load and are irradiated by light. When irradiated without any external electronic load, a PV device generates its maximum possible voltage, V open-circuit, or V_{OC}. If a PV device is irradiated with its electrical contacts shorted, a maximum short-circuit current, or I_{SC}, is produced. When actually used to generate power, a PV device is connected to a finite resistive load and the power output is given by the product of the current and voltage, I×V. The maximum total power generated by a PV device is inherently incapable of exceeding the product, I_{SC}×V_{OC}. When the load value is optimized for maximum power extraction, the current and voltage have the values, Iₘₐₓ and Vₘₐₓ, respectively.

A figure of merit for solar cells is the fill factor, ff, defined as:

ff={IₘₐₓVₘₐₓ}/{I_{SC}V_{OC}} (1)

where ff is always less than 1, as I_{SC} and V_{OC} are never obtained simultaneously in actual use. Nonetheless, as ff approaches 1, the device has less series or internal resistance and thus delivers a greater percentage of the product of I_{SC} V_{OC} to the load under optimal conditions.

When electromagnetic radiation of an appropriate energy is incident upon a semiconductive organic material, for example, an organic molecular crystal (OMC) material, or a polymer, a photon can be absorbed to produce an excited molecular state. This is represented symbolically as S₀+hv→S₀*. Here S₀ and S₀* denote ground and excited molecular states, respectively. This energy absorption is associated with the promotion of an electron from a bound state in the HOMO, which may be a π-bond, to the LUMO, which may be a π*-bond, or equivalently, the promotion of a hole from the LUMO to the HOMO. In organic thin-film photoconductors, the generated molecular state is generally believed to be an exciton, i.e., an electron-hole pair in a bound state which is transported as a quasi-particle. The excitons can have an appreciable life-time before geminate recombination, which refers to the process of the original electron and hole recombining with each other, as opposed to recombination with holes or electrons from other pairs. To produce a photocurrent the electron-hole pair must become separated, typically at a donor-acceptor interface between two dissimilar contacting organic thin films. If the charges do not separate, they can recombine in a geminant recombination process, also known as quenching, either radiatively, by the emission of light of a lower energy than the incident light, or non-radiatively, by the production of heat. Either of these outcomes is undesirable in a photosensitive optoelectronic device.

Electric fields or inhomogeneities at a contact may cause an exciton to quench rather than dissociate at the donor-acceptor interface, resulting in no net contribution to the current. Therefore, it is desirable to keep photogenerated excitons away from the contacts. This has the effect of limiting the diffusion of excitons to the region near the junction so that the associated electric field has an increased opportunity to separate charge carriers liberated by the dissociation of the excitons near the junction.

To produce internally generated electric fields which occupy a substantial volume, the usual method is to juxtapose two layers of material with appropriately selected conductive properties, especially with respect to their distribution of molecular quantum energy states. The interface of these two materials is called a photovoltaic heterojunction. In traditional semiconductor theory, materials for forming PV heterojunctions have been denoted as generally being of either n, or donor, type or p, or acceptor, type. Here n-type denotes that the majority carrier type is the electron. This could be viewed as the material having many electrons in relatively free energy states. The p-type denotes that the majority carrier type is the hole. Such material has many holes in relatively free energy states. The type of the background, i.e., not photo-generated, majority carrier concentration depends primarily on unintentional doping by defects or impurities. The type and concentration of impurities determine the value of the Fermi energy, or level, within the gap between the highest occupied molecular orbital (HOMO) and the lowest unoccupied molecular orbital (LUMO), called the HOMO-LUMO gap. The Fermi energy characterizes the statistical occupation of molecular quantum energy states denoted by the value of energy for which the probability of occupation is equal to ½. A Fermi energy near the LUMO energy indicates that electrons are the predominant carrier. A Fermi energy near the HOMO energy indicates that holes are the predominant carrier. Accordingly, the Fermi energy is a primary characterizing property of traditional semiconductors and the prototypical PV heterojunction has traditionally been the p-n interface.

The term “rectifying” denotes, inter alia, that an interface has an asymmetric conduction characteristic, i.e., the interface supports electronic charge transport preferably in one direction. Rectification is associated normally with a built-in electric field which occurs at the heterojunction between appropriately selected materials.

A significant property in organic semiconductors is carrier mobility. Mobility measures the ease with which a charge carrier can move through a conducting material in response to an electric field. As opposed to free carrier concentrations, carrier mobility is determined in large part by intrinsic properties of the organic material such as crystal symmetry and periodicity. Appropriate symmetry and periodicity can produce higher quantum wavefunction overlap of HOMO levels producing higher hole mobility, or similarly, higher overlap of LUMO levels to produce higher electron mobility. Moreover, the donor or acceptor nature of an organic semiconductor, e.g., 3,4,9,10-perylenetetracarboxylic dianhydride (PTCDA), may be at odds with the higher carrier mobility. For example, while chemistry arguments suggest a donor, or n-type, character for PTCDA, experiments indicate that hole mobilities exceed electron mobilities by several orders of magnitude so that the hole mobility is a critical factor. The result is that device configuration predictions from donor/acceptor criteria may not be borne out by actual device performance. Due to these unique electronic properties of organic materials, rather than designating them as “p-type” and “n-type”, the nomenclature of “hole-transporting-layer” (HTL) or “donor-type” or “electron-transporting-layer” (ETL) or “acceptor-type” is frequently used. In this designation scheme, an ETL will be preferentially electron conducting and an HTL will be preferentially hole transporting.

Conventional inorganic semiconductor PV cells employ a p-n junction to establish an internal field. Early organic thin film cell, such as reported by Tang, Appl. Phys Lett. 48, 183 (1986), contain a heterojunction analogous to that employed in a conventional inorganic PV cell. However, it is now recognized that in addition to the establishment of a pn type junction, the energy level offset of the heterojunction also plays an important role.

The energy level offset at the heterojunction is believed to be important to the operation of organic PV devices due to the fundamental nature of the photogeneration process in organic materials. Upon optical excitation of an organic material, localized Frenkel or charge-transfer excitons are generated. For electrical detection or current generation to occur, the bound excitons must be dissociated into their constituent electrons and holes. Such a process can be induced by the built-in electric field, but the efficiency at the electric fields typically found in organic devices (F˜10⁶ V/cm) is low. The most efficient exciton dissociation in organic materials occurs at a donor-acceptor (DN) interface. At such an interface, the donor material with a low ionization potential forms a heterojunction with an acceptor material with a high electron affinity. Depending on the alignment of the energy levels of the donor and acceptor materials, the dissociation of the exciton can become energetically favorable at such an interface, leading to a free electron polaron in the acceptor material and a free hole polaron in the donor material.

Organic PV cells have many potential advantages when compared to traditional silicon-based devices. Organic PV cells are light weight, economical in materials use, and can be deposited on low cost substrates, such as flexible plastic foils. However, organic PV devices typically have relatively low quantum yield (the ratio of photons absorbed to carrier pairs generated, or electromagnetic radiation to electricity conversion efficiency), being on the order of 1% or less. This is, in part, thought to be due to the second order nature of the intrinsic photoconductive process. That is, carrier generation requires exciton generation, diffusion and ionization. However, the diffusion length (L_{D}) of an exciton is typically much less (L_{D}˜50 Å) than the optical absorption length (˜500 Å), requiring a trade off between using a thick, and therefore resistive, cell with multiple or highly folded interfaces, or a thin cell with a low optical absorption efficiency. Different approaches to increase the efficiency have been demonstrated, including use of doped organic single crystals, conjugated polymer blends, and use of materials with increased exciton diffusion length. The problem was attacked yet from another direction, namely employment of different cell geometry, such as three-layered cell, having an additional mixed layer of co-deposited donor-type and acceptor-type materials, or fabricating a tandem cell.

Typically, when light is absorbed to form an exciton in an organic thin film, a singlet exciton is formed. By the mechanism of intersystem crossing, the singlet exciton may decay to a triplet exciton. In this process energy is lost which will result in a lower efficiency for the device. If not for the energy loss from intersystem crossing, it would be desirable to use triplet excitons, as they generally have a longer lifetime, and therefore a longer diffusion length, than do singlet excitons.

Through the use of an organometallic material in the photoactive region, the devices of the present invention may efficiently utilize triplet excitons. We have found that the singlet-triplet mixing may be so strong for organometallic compounds, that the absorptions involve excitation from the singlet ground states directly to the triplet excited states, eliminating the losses associated with conversion from the singlet excited state to the triplet excited state. The longer lifetime and diffusion length of triplet excitons in comparison to singlet excitons may allow for the use of a thicker photoactive region, as the triplet excitons may diffuse a greater distance to reach the donor-acceptor heterojunction, without sacrificing device efficiency.

### SUMMARY OF THE INVENTION

The present invention provides organic-based photosensitive optoelectronic devices. The devices of the present invention comprise an anode, a cathode and a photoactive region between the anode and the cathode, wherein the photoactive region comprises a cyclometallated organometallic compound. Advantageously, the device also includes one or more additional layers, such as blocking layers and a cathode smoothing layer.

In a preferred embodiment, the present invention provides an organic photosensitive optoelectronic device having a photoactive region comprising a cyclometallated organometallic material having the formula I

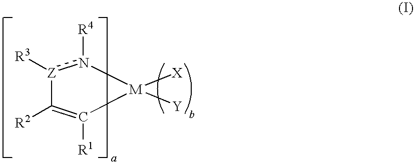

wherein
M is a transition metal having a molecular weight greater than 40;

### Z is N or C,

the dotted line represents an optional double bond,
R¹, R², R³ and R⁴ are independently selected from H, alkyl, or aryl, and additionally or alternatively, one or more of R¹ and R², R² and R³, and R³ and R⁴ together from independently a 5 or 6-member cyclic group, wherein said cyclic group is cycloalkyl, cycloheteroalkyl, aryl or heteroaryl; and wherein said cyclic group is optionally substituted by one or more substituents Q; each substituent Q is independently selected from the group consisting of alkyl, alkenyl, alkynyl, aralkyl, CN, CF₃, NR₂, NO₂, OR, halo, and aryl, and additionally, or alternatively, two Q groups on adjacent ring atoms form a fused 5- or 6-membered aromatic group;
each R is independently selected from H, alkyl, aralkyl, aryl and heteroaryl;
(X and Y), separately or in combination, are an ancillary ligand;
a is 1 to 3; and
b is 0 to 2;
with the proviso that the sum of a and b is 2 or 3.

In a further embodiment, the present invention provides an organic photosensitive optoelectronic device having a photoactive region comprising a cyclometallated organometallic material having the formula II

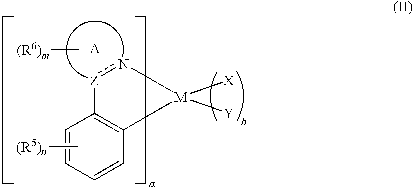

wherein
M is a transition metal having a molecular weight greater than 40;
ring A is an aromatic heterocyclic ring or a fused aromatic heterocyclic ring with at least one nitrogen atom that coordinates to the metal M;
Z is selected from carbon or nitrogen;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4;
m is 0 to 4;
a is 1 to 3; and
b is 0 to 2;
with the proviso that the sum of a and b is 2 or 3.

It is an object of the present invention to provide an organic PV device with improved photovoltaic performance. To this end, the invention provides an organic PV device capable of operating with a high external quantum efficiency.

Another object of the present invention is to provide organic photosensitive optoelectronic devices with improved absorption of incident radiation for more efficient photogeneration of charge carriers.

### BRIEF DESCRIPTION OF THE DRAWINGS

The foregoing and other features of the present invention will be more readily apparent from the following detailed description of exemplary embodiments taken in conjunction with the attached drawings.

FIG. 1 shows an organic PV device comprising an anode, an anode smoothing layer, a donor layer, an acceptor layer, a blocking layer, and a cathode.

FIG. 2 shows the absorption spectra of (ppy)Pt(dpm).

FIG. 3 shows the absorption spectra of (5′-N(CH₃)₂)ph-pyr)Pt(dpm).

FIG. 4 shows the absorption spectra of (5′-N(CH₃)₂)ph-5-NO₂pyr)Pt(dpm).

FIG. 5 shows the absorption spectra of (5′-N(CH₃)₂)ph-5-NO₂pyr)₂Ir(dpm).

FIG. 6 the three dimensional structure of a stacked chain of (4′,6′-F₂ ppy)Pt(dpm) molecules.

FIG. 7 shows partial structures of cyclometallated organometallic molecules with extended π-systems for use in red shifting the absorbance into the near-IR. The substituents A and D represent possible electron-acceptor or electron donor groups.

FIG. 8 shows the chemical structures of (ppy)Pt(dpm), (5′-N(CH₃)₂)ph-pyr)Pt(dpm), (4′-N(CH₃)₂ph-5-NO₂pyr)Pt(dpm), (4′-N(CH₃)₂ph-4-NO₂pyr)Pt(dpm), (5′-N(CH₃)₂)ph-5-NO₂pyr)Pt(dpm), (5′-N(CH₃)₂ph-4-NO₂pyr)Pt(dpm), (4′-N(CH₃)₂ph-5-NO₂pyr)₂Ir(dpm), (4′-N(CH₃)₂ph-4-NO₂pyr)₂Ir(dpm), (5′-N(CH₃)₂)ph-5-NO₂pyr)₂Ir(dpm), (5′-N(CH₃)₂ph-4-NO₂pyr)₂Ir(dpm), (pq)₂Ir(dpm), (ipq)₂Ir(dpm), (4′,6′-F₂ ppy)Pt(dpm), and (4,6′-F₂ ppy)₂Pt₂(SPy)₂.

FIG. 9 shows the crystal structure of the Pt dimer, (4′,6′-F₂ ppy)₂Pt₂(SPy)₂, and the oligomerization reaction for dimers.

FIG. 10 shows the absorption spectrum of copper phthalocyanine (Cupc).

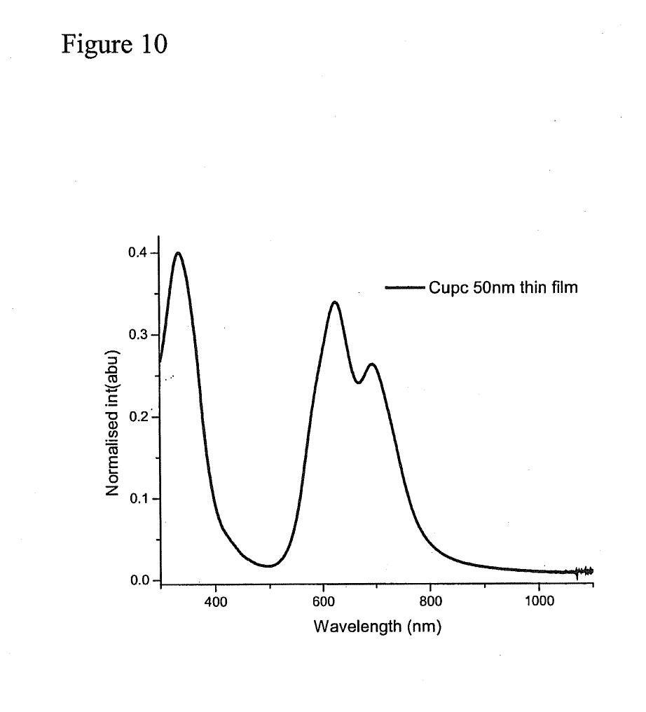

FIG. 11 shows the absorption spectrum lead phthalocyanine (Pbpc).

FIG. 12 shows the absorption spectrum of the aggregated dimer, FPtblue. The spectra of Cupc and Pbpc are shown in FIGS. 10 and 11 for comparison.

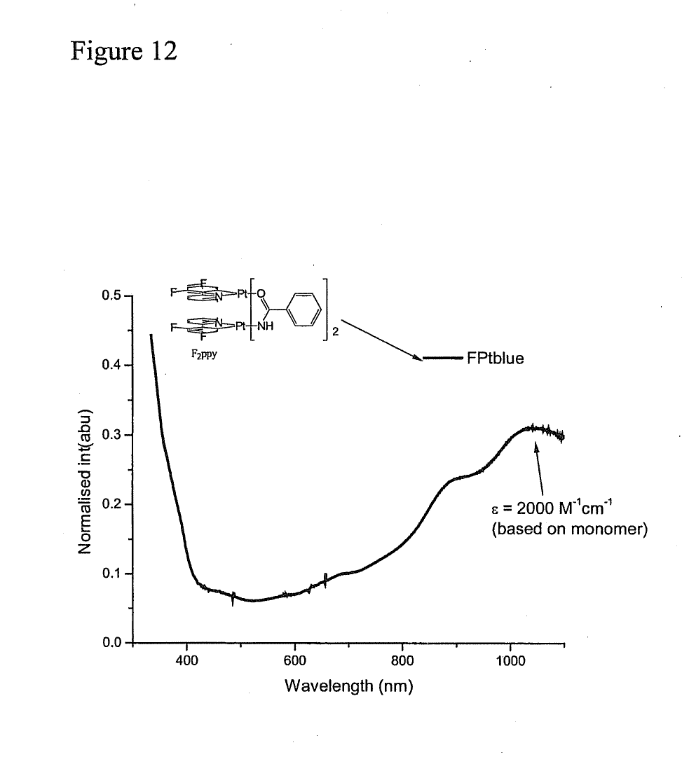

FIG. 13 shows the extinction coefficient of the ligand 4′-N(CH₃)₂ph-5-NO₂pyr in dichloromethane.

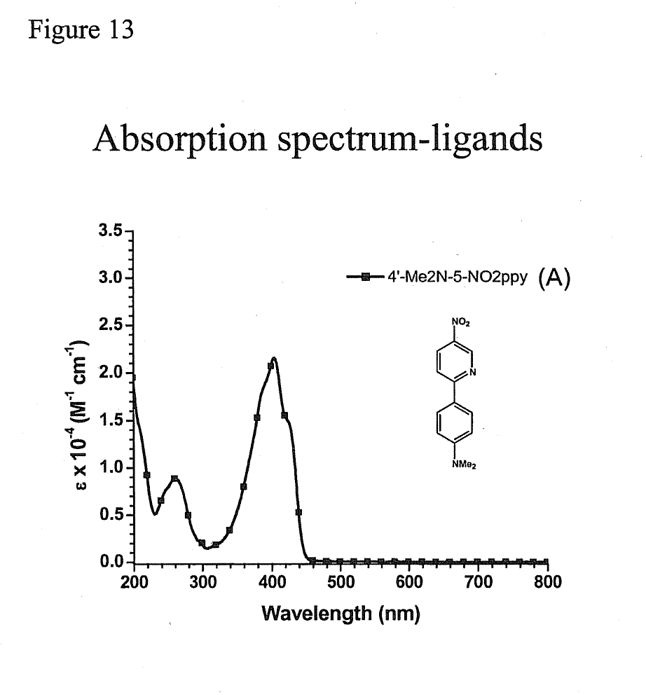

FIG. 14 shows the extinction coefficient of the ligand 4′-N(CH₃)₂ph-4-NO₂pyr.

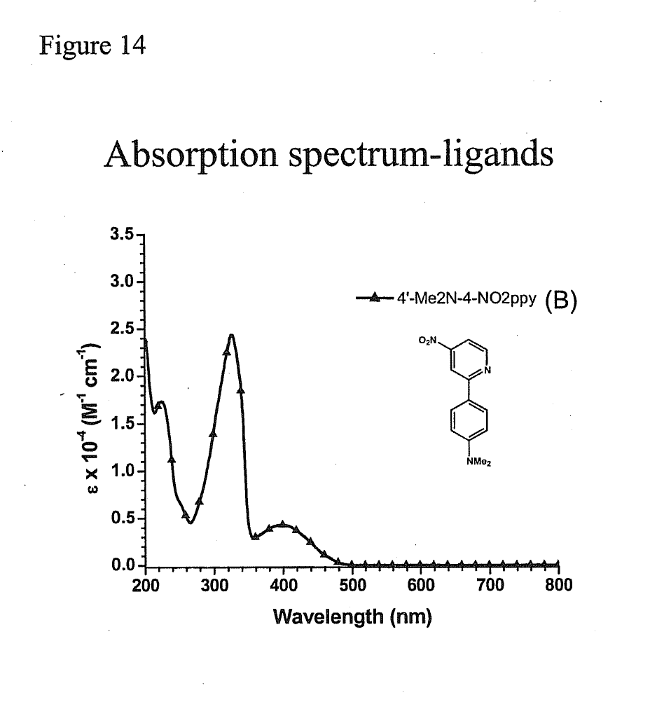

FIG. 15 shows the extinction coefficient of the ligand 3′-N(CH₃)₂ph-5-NO₂pyr.

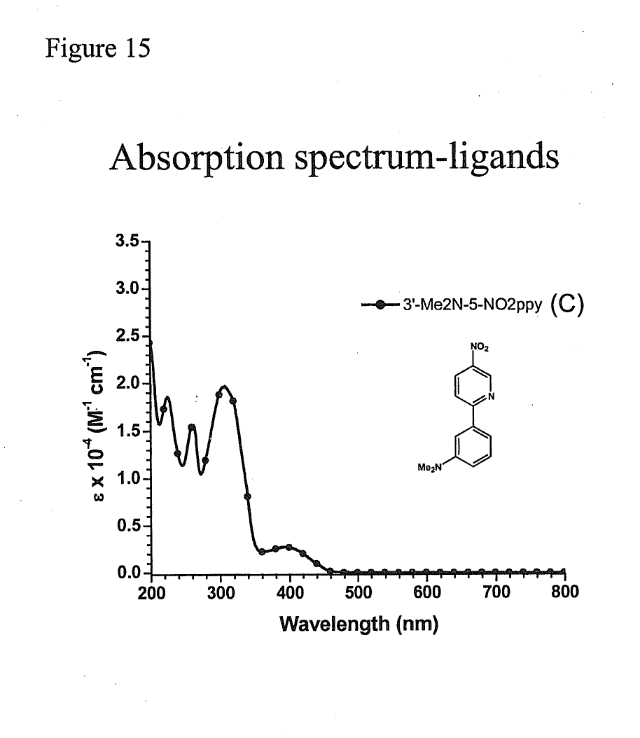

FIG. 16 shows the extinction coefficient of the ligand 3′-N(CH₃)₂ph-4-NO₂pyr.

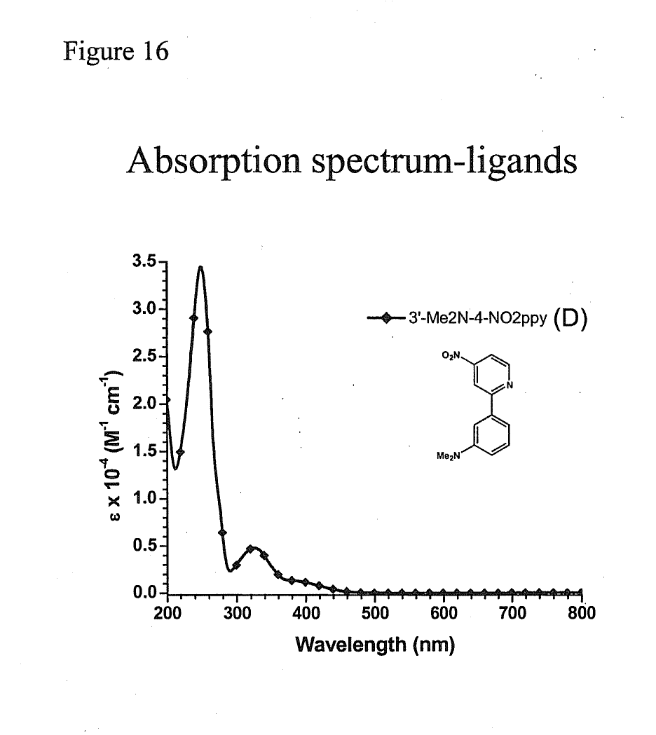

FIG. 17 shows the extinction coefficient of the Pt complex (4′-N(CH₃)₂ph-5-NO₂pyr)Pt(dpm).

FIG. 18 shows the extinction coefficient of the Pt complex (4′-N(CH₃)₂ph-4-NO₂pyr)Pt(dpm) in dichloromethane.

FIG. 19 shows the extinction coefficient of the Pt complex (5′-N(CH₃)₂ph-5-NO₂pyr)Pt(dpm).

FIG. 20 shows the extinction coefficient of the Pt complex (5′-N(CH₃)₂ph-4-NO₂pyr)Pt(dpm).

FIG. 21 shows the extinction coefficient of the Ir complex (4′-N(CH₃)₂ph-5-NO₂pyr)₂Ir(dpm).

FIG. 22 shows the extinction coefficient of the Ir complex (4′-N(CH₃)₂ph-4-NO₂pyr)₂Ir(dpm).

FIG. 23 shows the extinction coefficient of the Ir complex (5′-N(CH₃)₂)ph-5-NO₂pyr)₂Ir(dpm).

FIG. 24 shows the extinction coefficient of the Ir complex (5′-N(CH₃)₂ph-4-NO₂pyr)₂Ir(dpm).

FIG. 25 shows the extinction coefficient, excitation spectrum and emission spectrum of the Pt complex, (5′-N(CH₃)₂ph-5-NO₂pyr)Pt(dpm), in frozen 2-methyltetrahydrofuran (2-MeTHF) at 77K.

### DETAILED DESCRIPTION

The present invention provides an organic photosensitive optoelectronic device. The organic devices of the present invention may be used, for example, to generate a usable electrical current (e.g., solar cells) or may be used to detect incident electromagnetic radiation. The organic photosensitive optoelectronic devices of the present invention comprise an anode, a cathode, and an photoactive region between the anode and the cathode. The photoactive region is the portion of the photosensitive device that absorbs electromagnetic radiation to generate excitons that may dissociate in order to generate an electrical current. The active region of the organic devices described herein comprises a cyclometallated organometallic compound. The organic photosensitive optoelectronic devices may also include at least one transparent electrode to allow incident radiation to be absorbed by the device. Several PV device materials and configurations are described in U.S. Pat. Nos. 6,657,378, 6,580,027, and 6,352,777, which are incorporated herein by reference in their entirety.

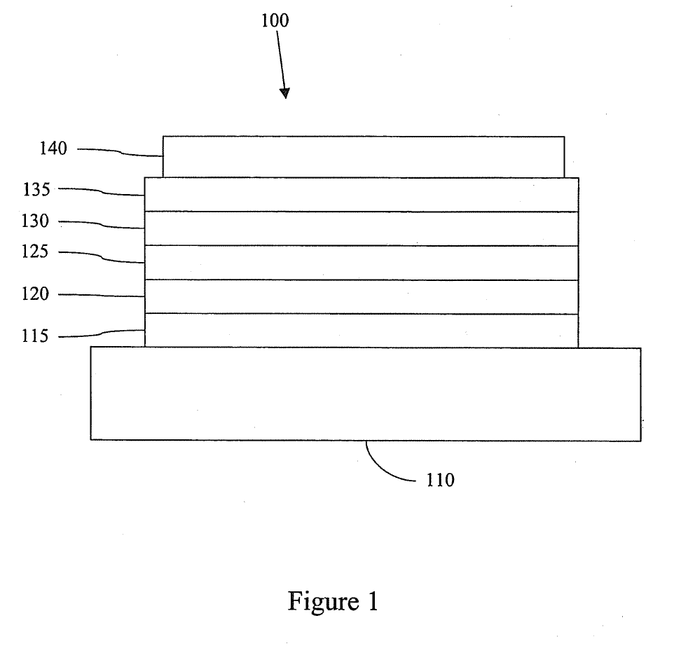

FIG. 1 shows an organic photosensitive optoelectronic device 100. The figures are not necessarily drawn to scale. Device 100 may include a substrate 110, an anode 115, an anode smoothing layer 120, a donor layer 125, an acceptor layer 130, a blocking layer 135, and a cathode 140. Cathode 160 may be a compound cathode having a first conductive layer and a second conductive layer. Device 100 may be fabricated by depositing the layers described, in order.

The substrate may be any suitable substrate that provides desired structural properties. The substrate may be flexible or rigid. The substrate may be transparent, translucent or opaque. Plastic and glass are examples of preferred rigid substrate materials. Plastic and metal foils are examples of preferred flexible substrate materials. The material and thickness of the substrate may be chosen to obtain desired structural and optical properties.

The electrodes, or contacts, used in a photosensitive optoelectronic device are an important consideration, as shown in co-pending application Ser. No. 09/136,342, incorporated herein by reference. When used herein, the terms “electrode” and “contact” refer to layers that provide a medium for delivering photo-generated current to an external circuit or providing a bias voltage to the device. That is, an electrode, or contact, provides the interface between the photoconductively active regions of an organic photosensitive optoelectronic device and a wire, lead, trace or other means for transporting the charge carriers to or from the external circuit. In a photosensitive optoelectronic device, it is desirable to allow the maximum amount of ambient electromagnetic radiation from the device exterior to be admitted to the photoconductively active interior region. That is, the electromagnetic radiation must reach a photoconductive layer(s), where it can be converted to electricity by photoconductive absorption. This often dictates that at least one of the electrical contacts should be minimally absorbing and minimally reflecting of the incident electromagnetic radiation. That is, such a contact should be substantially transparent. The opposing electrode may be a reflective material so that light which has passed through the cell without being absorbed is reflected back through the cell. As used herein, a layer of material or a sequence of several layers of different materials is said to be “transparent” when the layer or layers permit at least 50% of the ambient electromagnetic radiation in relevant wavelengths to be transmitted through the layer or layers. Similarly, layers which permit some, but less that 50% transmission of ambient electromagnetic radiation in relevant wavelengths are said to be “semi-transparent”.

As used herein, “top” means furthest away from the substrate, while “bottom” means closest to the substrate. For example, for a device having two electrodes, the bottom electrode is the electrode closest to the substrate, and is generally the first electrode fabricated. The bottom electrode has two surfaces, a bottom surface closest to the substrate, and a top surface further away from the substrate. Where a first layer is described as “disposed over” a second layer, the first layer is disposed further away from substrate. There may be other layers between the first and second layer, unless it is specified that the first layer is “in physical contact with” the second layer. For example, a cathode may be described as “disposed over” an anode, even though there are various organic layers in between.

The electrodes are preferably composed of metals or “metal substitutes”. Herein the term “metal” is used to embrace both materials composed of an elementally pure metal, e.g., Mg, and also metal alloys which are materials composed of two or more elementally pure metals, e.g., Mg and Ag together, denoted Mg:Ag. Here, the term “metal substitute” refers to a material that is not a metal within the normal definition, but which has the metal-like properties that are desired in certain appropriate applications. Commonly used metal substitutes for electrodes and charge transfer layers would include doped wide-bandgap semiconductors, for example, transparent conducting oxides such as indium tin oxide (ITO), gallium indium tin oxide (GITO), and zinc indium tin oxide (ZITO). In particular, ITO is a highly doped degenerate n+ semiconductor with an optical bandgap of approximately 3.2 eV, rendering it transparent to wavelengths greater than approximately 3900 Å. Another suitable metal substitute is the transparent conductive polymer polyanaline (PANI) and its chemical relatives. Metal substitutes may be further selected from a wide range of non-metallic materials, wherein the term “non-metallic” is meant to embrace a wide range of materials provided that the material is free of metal in its chemically uncombined form. When a metal is present in its chemically uncombined form, either alone or in combination with one or more other metals as an alloy, the metal may alternatively be referred to as being present in its metallic form or as being a “free metal”. Thus, the metal substitute electrodes of the present invention may sometimes be referred to as “metal-free” wherein the term “metal-free” is expressly meant to embrace a material free of metal in its chemically uncombined form. Free metals typically have a form of metallic bonding that results from a sea of valence electrons which are free to move in an electronic conduction band throughout the metal lattice. While metal substitutes may contain metal constituents they are “non-metallic” on several bases. They are not pure free-metals nor are they alloys of free-metals. When metals are present in their metallic form, the electronic conduction band tends to provide, among other metallic properties, a high electrical conductivity as well as a high reflectivity for optical radiation.

Embodiments of the present invention may include, as one or more of the transparent electrodes of the photosensitive optoelectronic device, a highly transparent, non-metallic, low resistance cathode such as disclosed in U.S. Pat. No. 6,420,031, to Parthasarathy et al. (“Parthasarathy '031”), or a highly efficient, low resistance metallic/non-metallic compound cathode such as disclosed in U.S. Pat. No. 5,703,436 to Forrest et al. (“Forrest '436”), both incorporated herein by reference in their entirety. Each type of cathode is preferably prepared in a fabrication process that includes the step of sputter depositing an ITO layer onto either an organic material, such as copper phthalocyanine (CuPc), to form a highly transparent, non-metallic, low resistance cathode or onto a thin Mg:Ag layer to form a highly efficient, low resistance metallic/non-metallic compound cathode. Parthasarathy '031 discloses that an ITO layer onto which an organic layer had been deposited, instead of an organic layer onto which the ITO layer had been deposited, does not function as an efficient cathode.

Herein, the term “cathode” is used in the following manner. In a non-stacked PV device or a single unit of a stacked PV device under ambient irradiation and connected with a resistive load and with no externally applied voltage, e.g., a solar cell, electrons move to the cathode from the photo-conducting material. Similarly, the term “anode” is used herein such that in a solar cell under illumination, holes move to the anode from the photo-conducting material, which is equivalent to electrons moving in the opposite manner. It will be noted that as the terms are used herein, anodes and cathodes may be electrodes or charge transfer layers.

An organic photosensitive device will comprise at least one photoactive region in which light is absorbed to form an excited state, or “exciton”, which may subsequently dissociate in to an electron and a hole. The dissociation of the exciton will typically occur at the heterojunction formed by the juxtaposition of an acceptor layer and a donor layer. The devices of the present invention comprise a photoactive region that comprises a cyclometallated organometallic material.

The acceptor material may be comprised of, for example, perylenes, naphthalenes, fullerenes or nanotubules. An example of an acceptor material is 3,4,9,10-perylenetetracarboxylic bis-benzimidazole (PTCBI). Alternatively, the acceptor layer may be comprised of a fullerene material as described in U.S. Pat. No. 6,580,027, incorporated herein by reference in its entirety. Adjacent to the acceptor layer, is a layer of organic donor-type material. The boundary of the acceptor layer and the donor layer forms the heterojunction which may produce an internally generated electric field. The material for the donor layer may be a pthalocyanine or a porphyrin, or a derivative or transition metal complex thereof, such as copper pthalocyanine (CuPc). In one embodiment of the invention, the acceptor material or the donor material may be selected from an inorganic semiconducting material.

In a preferred embodiment of the invention, the stacked organic layers include one or more exciton blocking layers (EBLs) as described in U.S. Pat. No. 6,097,147, Peumans et al, Applied Physics Letters 2000, 76, 2650-52, and co-pending application Ser. No. 09/449,801, filed Nov. 26, 1999, both incorporated herein by reference. Higher internal and external quantum efficiencies have been achieved by the inclusion of an EBL to confine photogenerated excitons to the region near the dissociating interface and to prevent parasitic exciton quenching at a photosensitive organic/electrode interface. In addition to limiting the volume over which excitons may diffuse, an EBL can also act as a diffusion barrier to substances introduced during deposition of the electrodes. In some circumstances, an EBL can be made thick enough to fill pinholes or shorting defects which could otherwise render an organic PV device non-functional. An EBL can therefore help protect fragile organic layers from damage produced when electrodes are deposited onto the organic materials.

It is believed that the EBLs derive their exciton blocking property from having a LUMO-HOMO energy gap substantially larger than that of the adjacent organic semiconductor from which excitons are being blocked. Thus, the confined excitons are prohibited from existing in the EBL due to energy considerations. While it is desirable for the EBL to block excitons, it is not desirable for the EBL to block all charge. However, due to the nature of the adjacent energy levels, an EBL will necessarily block one sign of charge carrier. By design, an EBL will always exist between two layers, usually an organic photosensitive semiconductor layer and a electrode or charge transfer layer. The adjacent electrode or charge transfer layer will be in context either a cathode or an anode. Therefore, the material for an EBL in a given position in a device will be chosen so that the desired sign of carrier will not be impeded in its transport to the electrode or charge transfer layer. Proper energy level alignment ensures that no barrier to charge transport exists, preventing an increase in series resistance. For example, it is desirable for a material used as a cathode side EBL to have a LUMO level closely matching the LUMO level of the adjacent ETL material so that any undesired barrier to electrons is minimized.

It should be appreciated that the exciton blocking nature of a material is not an intrinsic property of its HOMO-LUMO energy gap. Whether a given material will act as an exciton blocker depends upon the relative HOMO and LUMO levels of the adjacent organic photosensitive material. Therefore, it is not possible to identify a class of compounds in isolation as exciton blockers without regard to the device context in which they may be used. However, with the teachings herein one of ordinary skill in the art may identify whether a given material will function as an exciton blocking layer when used with a selected set of materials to construct an organic PV device.

In a preferred embodiment of the invention, an EBL is situated between the acceptor layer and the cathode. A preferred material for the EBL comprises 2,9-dimethyl-4,7-diphenyl-1,10-phenanthroline (also called bathocuproine or BCP), which is believed to have a LUMO-HOMO separation of about 3.5 eV, or bis(2-methyl-8-hydroxyquinolinoato)-aluminum(III)phenolate (Alq₂OPH). BCP is an effective exciton blocker which can easily transport electrons to the cathode from an acceptor layer.

The EBL layer may be doped with a suitable dopant, including but not limited to 3,4,9,10-perylenetracarboxylic dianhydride (PTCDA), 3,4,9,10-perylenetracarboxylic diimide (PTCDI), 3,4,9,10-perylenetetracarboxylic-bis-benzimidazole (PTCBI), 1,4,5,8-naphthalenetetracarboxylic dianhydride (NTCDA), and derivatives thereof. It is thought that the BCP as deposited in the present devices is amorphous. The present apparently amorphous BCP exciton blocking layers may exhibit film recrystallization, which is especially rapid under high light intensities. The resulting morphology change to polycrystalline material results in a lower quality film with possible defects such as shorts, voids or intrusion of electrode material. Accordingly, it has been found that doping of some EBL materials, such as BCP, that exhibit this effect with a suitable, relatively large and stable molecule can stabilize the EBL structure to prevent performance degrading morphology changes. It should be further appreciated that doping of an EBL which is transporting electrons in a giving device with a material having a LUMO energy level close to that of the EBL will help insure that electron traps are not formed which might produce space charge build-up and reduce performance. Additionally, it should be appreciated that relatively low doping densities should minimize exciton generation at isolated dopant sites. Since such excitons are effectively prohibited from diffusing by the surrounding EBL material, such absorptions reduce device photoconversion efficiency.

Representative embodiments may also comprise transparent charge transfer layers or charge recombination layers. As described herein charge transfer layers are distinguished from ETL and HTL layers by the fact that charge transfer layers are frequently, but not necessarily, inorganic and they are generally chosen not to be photoconductively active. The term “charge transfer layer” is used herein to refer to layers similar to but different from electrodes in that a charge transfer layer only delivers charge carriers from one subsection of an optoelectronic device to the adjacent subsection. The term “charge recombination layer” is used herein to refer to layers similar to but different from electrodes in that a charge recombination layer allows for the recombination of electrons and holes between tandem photosensitive devices and to enhance internal optical field near one or more active layers. A charge recombination layer can be constructed of semi-transparent metal nanoclusters, nanoparticle or nanorods as described in U.S. Pat. No. 6,657,378, incorporated herein by reference in its entirety.

In another preferred embodiment of the invention, an anode-smoothing layer is situated between the anode and the donor layer. A preferred material for this layer comprises a film of 3,4-polyethylenedioxythiophene:polystyrenesulfonate (PEDOT:PSS). The introduction of the PEDOT:PSS layer between the anode (ITO) and the donor layer (CuPc) may lead to greatly improved fabrication yields. We attribute this to the ability of the spin-coated PEDOT:PSS film to planarize the ITO, whose rough surface could otherwise result in shorts through the thin molecular film.

In a further embodiment on the invention, one or more of the layers may be treated with plasma prior to depositing the next layer. The layers may be treated, for example, with a mild argon or oxygen plasma. This treatment is beneficial as it reduces the series resistance. It is particularly advantageous that the PEDOT:PSS layer be subject to a mild plasma treatment prior to deposition of the next layer.

The simple layered structure illustrated in FIG. 1 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting.

The devices of the present invention comprise a cyclometallated organometallic compound. The term “organometallic” as used herein is as generally understood by one of ordinary skill in the art and as given, for example, in “Inorganic Chemistry” (2nd Edition) by Gary L. Miessler and Donald A. Tarr, Pentice-Hall (1998). Thus, the term organometallic refers to compounds which have an organic group bonded to a metal through a carbon-metal bond. This class does not include per se coordination compounds, which are substances having only donor bonds, generally from heteroatoms, such as metal complexes of anines, halides, pseudohalides (CN, etc.), and the like. In practice organometallic compounds often comprise, in addition to one or more carbon-metal bonds to an organic species, one or more donor bonds from a heteroatom. The carbon-metal bond to an organic species refers to a direct bond between a metal and a carbon atom of an organic group, such as phenyl, alkyl, alkenyl, etc., but does not refer to a metal bond to an “inorganic carbon,” such as the carbon of CN. The term cyclometallated refers to compounds that comprise an bidentate organometallic ligand so that, upon bonding to a metal, a ring structure is formed that includes the metal as one of the ring members.

The organometallic compounds for use in the present invention have a number of general properties that make them good candidates for use in organic photosensitive optoelectronic devices. The organometallic compounds generally have much higher thermal stabilities than their organic counterparts, with organometallic compounds often having glass transition temperatures above 200° C. Another benefit of organometallic compounds, is the ease with which the HOMO and LUMO energies can be adjusted, without markedly affecting their molecular structures. Thus, it is possible to make a family of organometallic materials with gradually changing HOMO or LUMO energies, which may have similar solid state packing or glass forming properties, making the “tuning” of the device properties a straightforward process. In addition to tuning orbital energies, it is possible to tune the absorption bands for the organometallic compounds to fall anywhere in the visible to near-IR region, making these complexes ideal for harvesting the full solar spectrum. The organometallic compounds have also been shown to be potent oxidants and reductants in their excited states. This makes them an ideal class of materials for charge separation/creation in the PV cell. Lastly, with the proper ligand design it is possible to prepare organometallic compounds that preferentially stack into infinite π-π stacks (see below), which may lead to efficient exciton and/or carrier conduction.

In designing the organometallic materials for use in PV or solar cells it is important to keep a number of criteria in mind. If the organometallic material is meant to absorb light and be part of the charge generation network, it should have an absorption spectrum which matches the solar spectrum (or a fixed portion if multiple absorbing species are used) or particular ambient conditions (e.g., low-intensity fluorescent indoor light). It is preferable that the molar absorption for the material be high in order to minimize the amount of material that will be required in the PV cell as well as the exciton diffusion length within the device.

The chromophore bound exciton may dissociate at the donor-acceptor interface, giving the free hole and electron. The relative HOMO and LUMO energies of the metal complex and the material to which it will transfer charge are an important consideration. Thus, it is important to tune the HOMO and LUMO energies carefully to achieve the highest possible operating voltage.

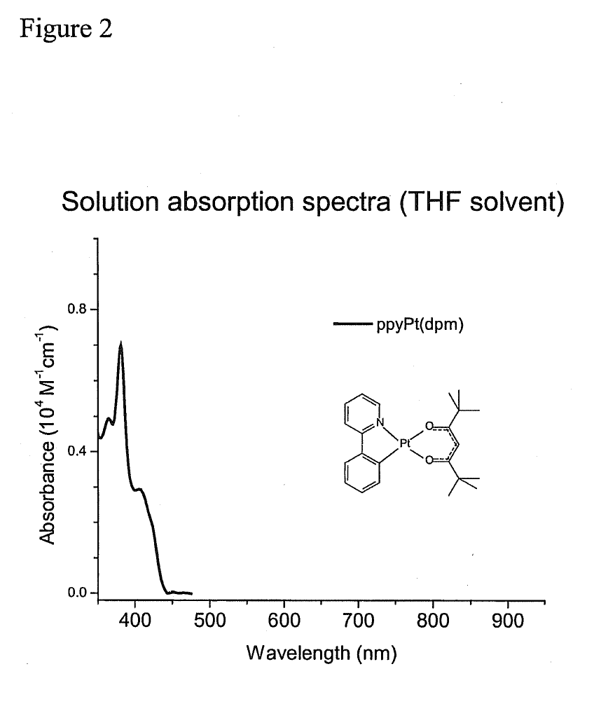

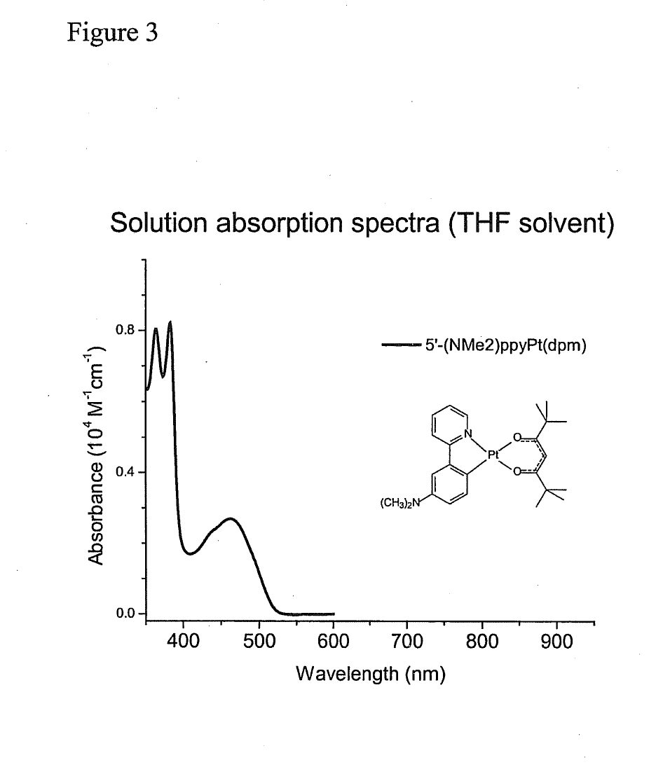

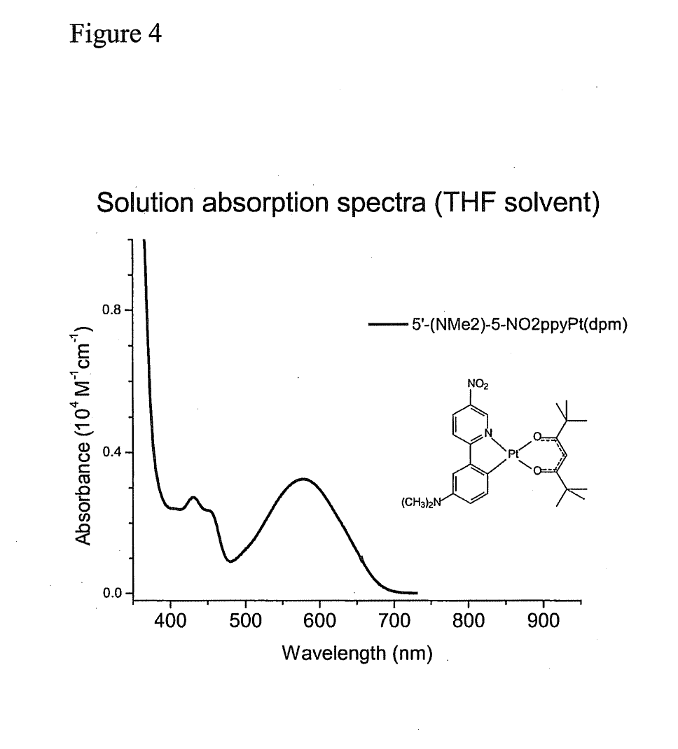

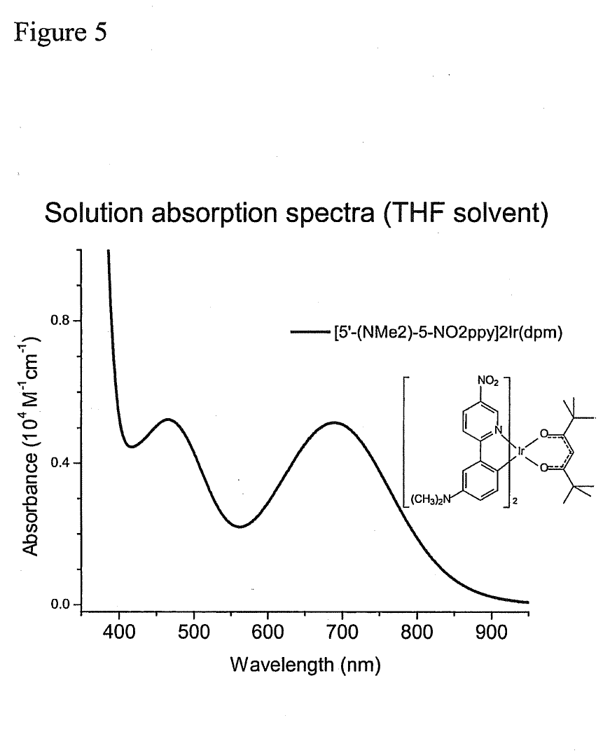

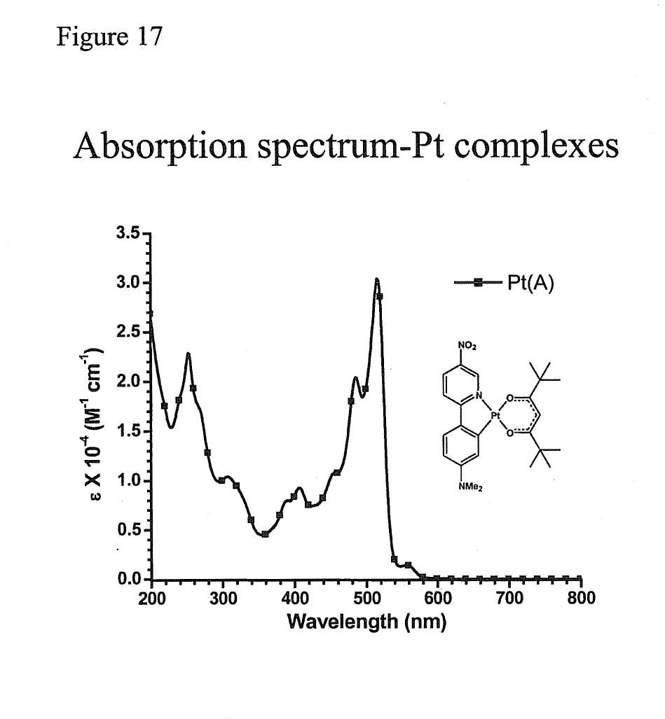

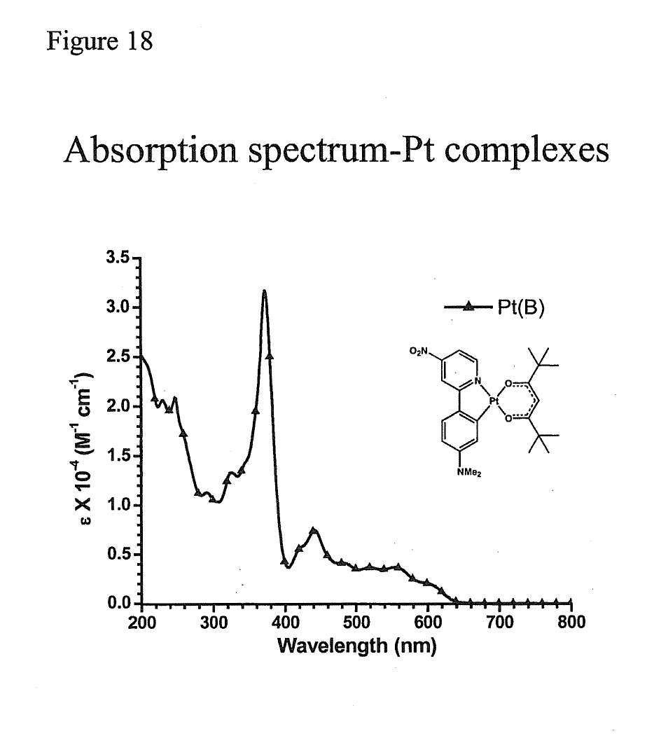

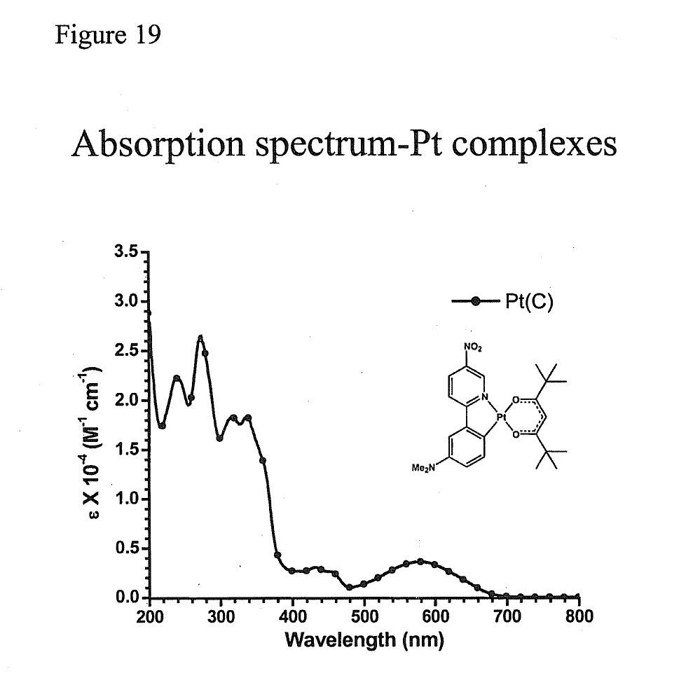

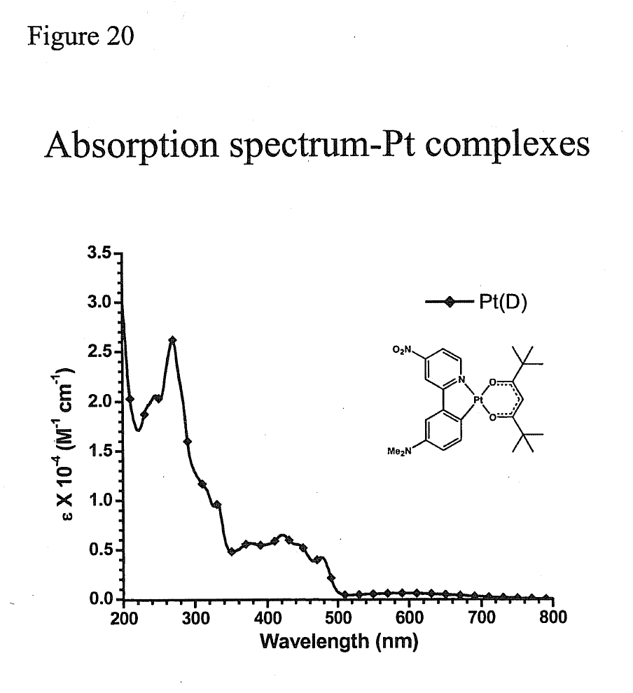

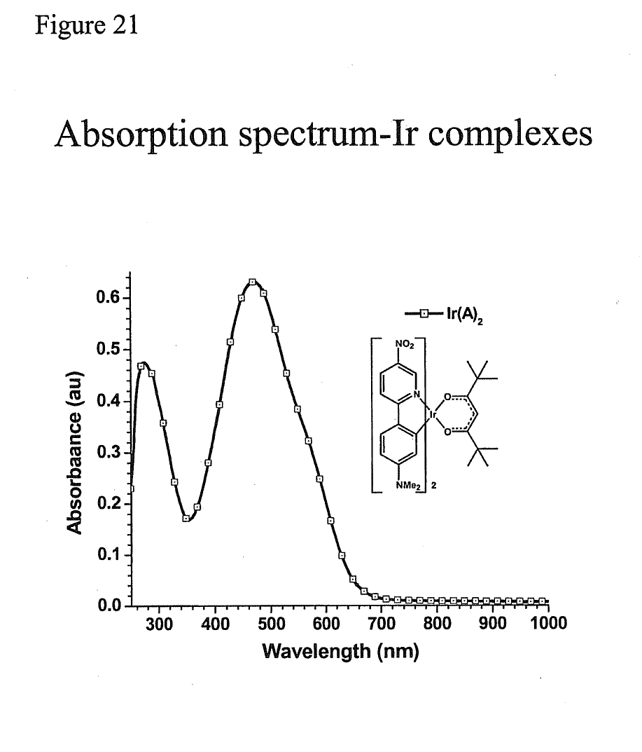

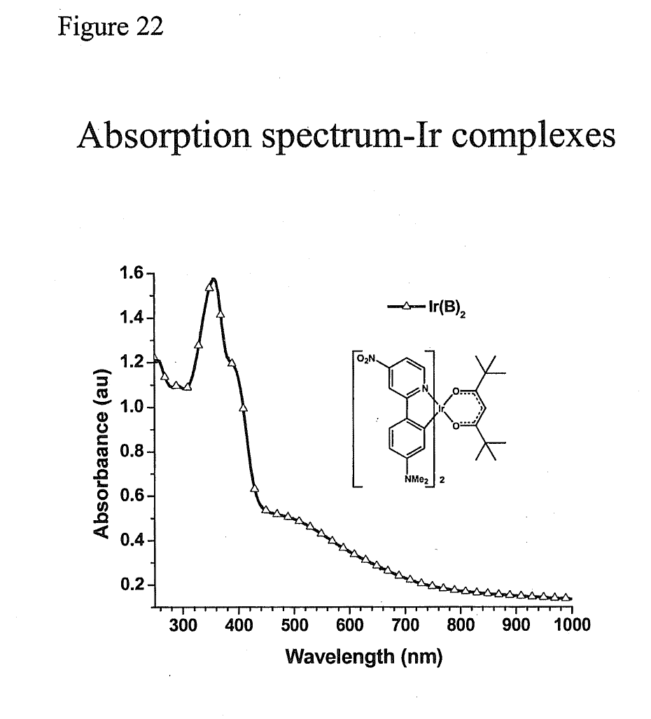

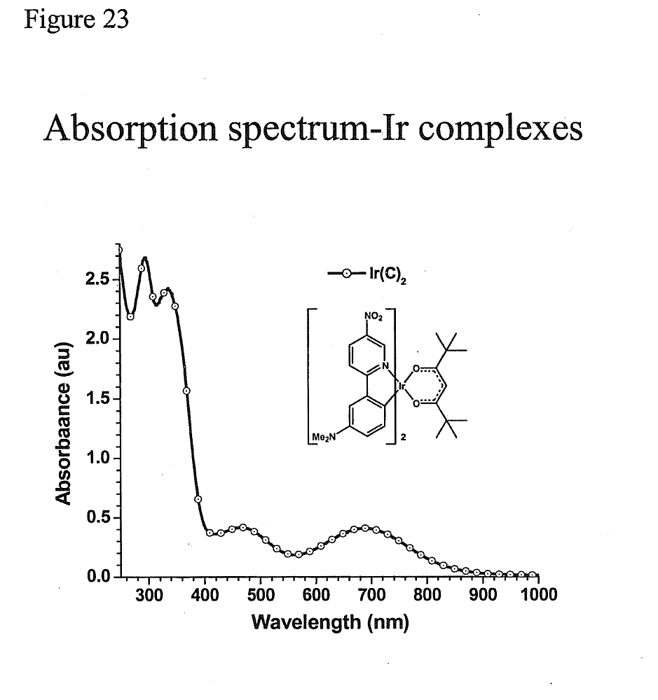

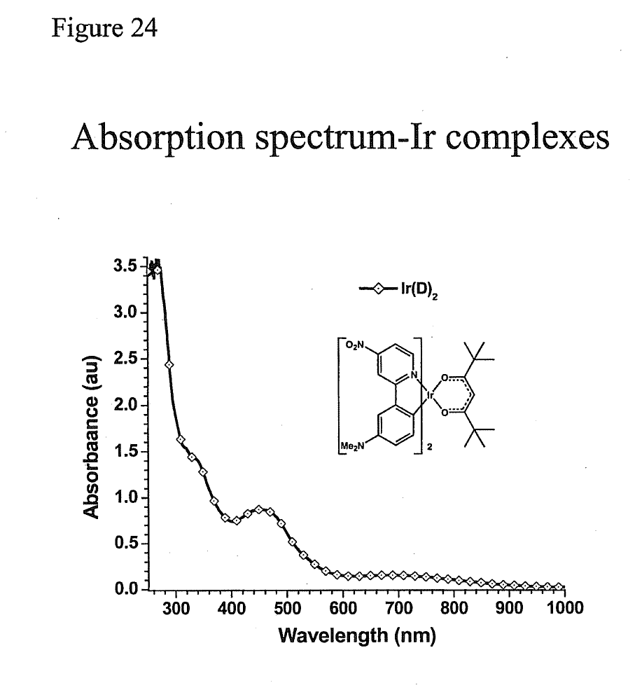

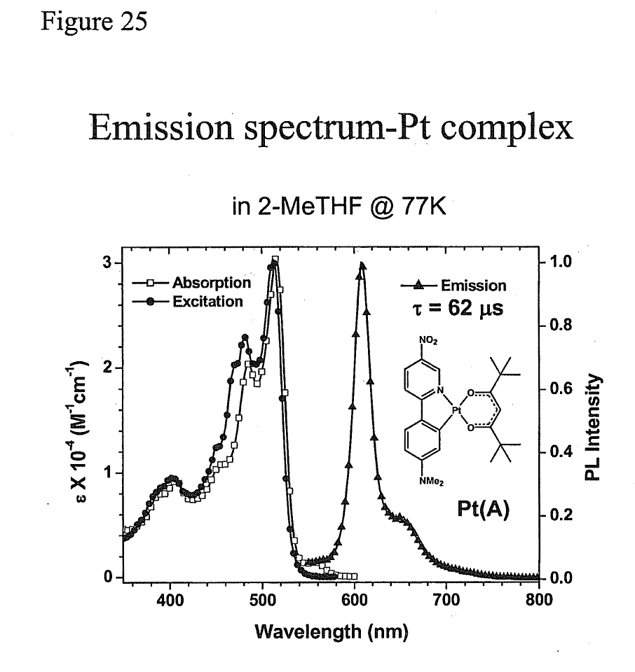

Processes that lead to excited states that are markedly lower in energy than the initial absorber generally should be avoided, as a significant loss in efficiency may result if the photon energy is largely lost in internal conversion processes. Two potential pathways that should be avoided for metal complexes are intersystem crossing (ISC) to triplet states and excimer formation. The use of an organometallic material is surprising as the high ISC efficiency typically found in these materials would quickly convert the singlet excited state formed on absorption of light to the a triplet state. However, we have found that the singlet-triplet mixing is so strong that the absorptions (as shown in FIGS. 2-5 and 17-25) involve excitation from the singlet ground states directly to the triplet excited states, thus eliminating the energy losses associated with conversion of the singlet excited state to the triplet excited state. Additionally, the triplet exciton that results generally will have a longer diffusion length as compared with a singlet exciton.

In a preferred embodiment, the present invention provides an organic photosensitive optoelectronic device having a photoactive region comprising a cyclometallated organometallic compound having the formula I

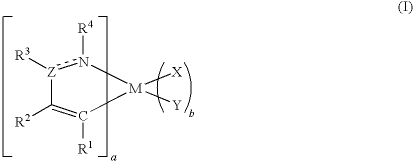

wherein
M is a transition metal having a molecular weight greater than 40;

### Z is N or C,

the dotted line represents an optional double bond,
R¹, R², R³ and R⁴ are independently selected from H, alkyl, or aryl, and additionally or alternatively, one or more of R¹ and R², R² and R³, and R³ and R⁴ together from independently a 5 or 6-member cyclic group, wherein said cyclic group is cycloalkyl, cycloheteroalkyl, aryl or heteroaryl; and wherein said cyclic group is optionally substituted by one or more substituents Q;
each substituent Q is independently selected from the group consisting of alkyl, alkenyl, alkynyl, aralkyl, CN, CF₃, NR₂, NO₂, OR, halo, and aryl, and additionally, or alternatively, two Q groups on adjacent ring atoms form a fused 5- or 6-membered aromatic group;
each R is independently selected from H, alkyl, aralkyl, aryl and heteroaryl;
(X and Y), separately or in combination, are an ancillary ligand;
a is 1 to 3; and
b is 0 to 2;
with the proviso that the sum of a and b is 2 or 3.

In a preferred embodiment, at least one of R¹ and R² or R³ and R⁴ together form a 5 or 6-membered aryl or heteroaryl ring. In a more preferred embodiment, both R¹ and R² together form a 5 or 6-membered aryl or heteroaryl ring, and R³ and R⁴ together from a 5 or 6-member aryl or heteroaryl ring.

The metal, M, is selected from the transition metals having an atomic weight greater than 40. Preferred metals include Ir, Pt, Pd, Rh, Re, Os, Tl, Pb, Bi, In, Sn, Sb, Te, Au, and Ag. More preferably, the metal is Ir or Pt.

The organometallic materials of the present invention may comprise one or more ancillary ligands, represented by (X-Y). These ligands are referred to as “ancillary” because it is believed that they may modify the photoactive properties of the molecule, as opposed to directly contributing to the photoactive properties. The definitions of photoactive and ancillary are intended as non-limiting theories. Ancillary ligands for use in the organometallic material may be selected from those known in the art. Non-limiting examples of ancillary ligands may be found in Cotton et al., Advanced Inorganic Chemistry, 1980, John Wiley & Sons, New York N.Y., and in PCT Application Publication WO 02/15645 A1 to Lamansky et al. at pages 89-90, both of which are incorporated herein by reference. Preferred ancillary ligands include acetylacetonate (acac) and picolinate (pic), and derivatives thereof. The preferred ancillary ligands have the following structures:

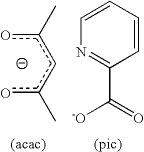

The number of “ancillary” ligands of a particular type, may be any integer from zero to one less than the maximum number if ligands that may be attached to the metal.

In a further embodiment, R¹ and R² together form a phenyl ring, and R³ and R⁴ together form a heteroaryl group to give a cyclometallated organometallic compound of the formula II

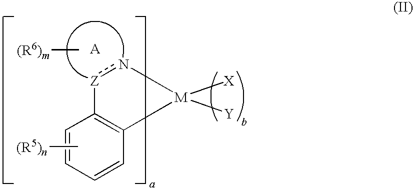

wherein
M is a transition metal having a molecular weight greater than 40;
ring A is an aromatic heterocyclic ring or a fused aromatic heterocyclic ring with at least one nitrogen atom that coordinates to the metal M;
Z is selected from carbon or nitrogen;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4;
m is 0 to 4;
a is 1 to 3; and
b is 0 to 2;
with the proviso that the sum of a and b is 2 or 3.

Ring A in formula II is an aromatic heterocyclic ring or a fused aromatic heterocyclic ring with at least one nitrogen atom that is coordinated to the metal M, wherein the ring can be optionally substituted. In a preferred embodiment, A is pyridine, pyrimidine, quinoline, or isoquinoline. Most preferable, A is a pyridine ring. Optional substituents on the Ring A include of alkyl, alkenyl, alkynyl, aralkyl, CN, CF₃, NR₂, NO₂, OR, halo, and aryl. A particularly preferred cyclometallating ligand is phenylpyridine, and derivatives thereof.

In a preferred embodiment, the ring A of the compounds of the formula II is a pyridine ring to give a cyclometallated organometallic compound having the formula III

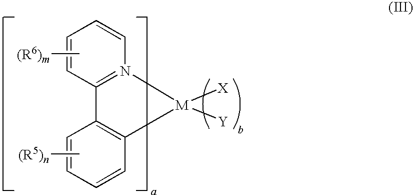

wherein
M is a transition metal having a molecular weight greater than 40;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4;
m is 0 to 4;
a is 1 to 3; and
b is 0 to 2;
with the proviso that the sum of a and b is 2 or 3.

In another embodiment of the invention, the organometallic compound may be a square planar compound, in which a=1 and b=1, to give a compound of the formula IV

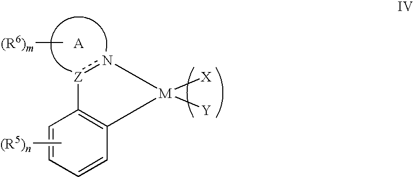

wherein
M is a transition metal having a molecular weight greater than 40;
ring A is an aromatic heterocyclic ring or a fused aromatic heterocyclic ring with at least one nitrogen atom that coordinates to the metal M;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

In a further embodiment of the compound of formula IV, the ring A is a pyridine ring, to give a compound having the formula V

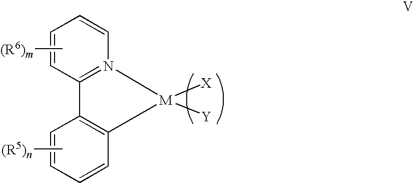

wherein
M is a transition metal having a molecular weight greater than 40;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

In another embodiment of the invention, the cyclometallated organometallic compound may be a compound of the formula II in which a=2 and b=1, to give a compound having the formula VI

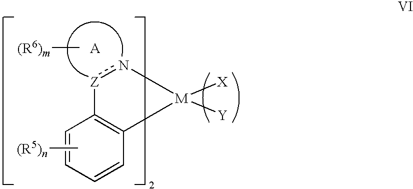

wherein
M is a transition metal having a molecular weight greater than 40;
ring A is an aromatic heterocyclic ring or a fused aromatic heterocyclic ring with at least one nitrogen atom that coordinates to the metal M;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

In a further embodiment of the compound of formula VI, the ring A is a pyridine ring, to give a compound having the formula VII

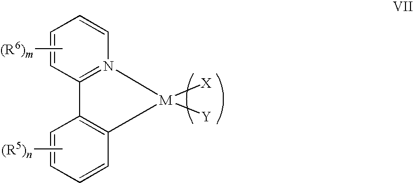

wherein
M is a transition metal having a molecular weight greater than 40;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

In another embodiment of the invention, the cyclometallated organometallic compound may be a compound of the formula II in which a=3 and b=0, to give a compound having the formula VIII

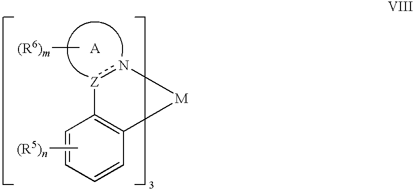

wherein
M is a transition metal having a molecular weight greater than 40;
ring A is an aromatic heterocyclic ring or a fused aromatic heterocyclic ring with at least one nitrogen atom that coordinates to the metal M;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

In a further embodiment of the compound of formula VIII, the ring A is a pyridine ring, to give a compound having the formula IX

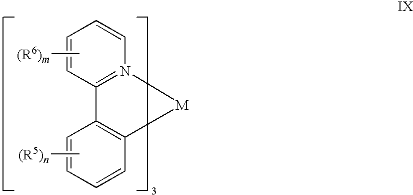

wherein
M is a transition metal having a molecular weight greater than 40;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

Many properties of the cyclometallated organometallic compounds described herein may be tuned by careful selection of the substituents. Properties that may be tuned include the absorption band, HOMO/LUMO energies, oxidation/reduction characteristics, etc. An example of the tunability of the absorption spectra for these organometallic materials is shown in FIGS. 2-5. The four complexes have phenylpyridine (ppy) type ligands. By adding electron donating and/or accepting groups (for example, —NMe₂ and —NO₂, respectively) to the ppy ligands, the absorption bands may be shifted from the UV/violet to the near-IR, all with extinction coefficient consistent with fully allowed transitions (i.e. ε>1000 M⁻¹ cm⁻¹). The NMe₂ and NO₂ substituted Pt and Ir complexes are stable to sublimation, making them excellent candidates for solar cells prepared by vapor deposition.

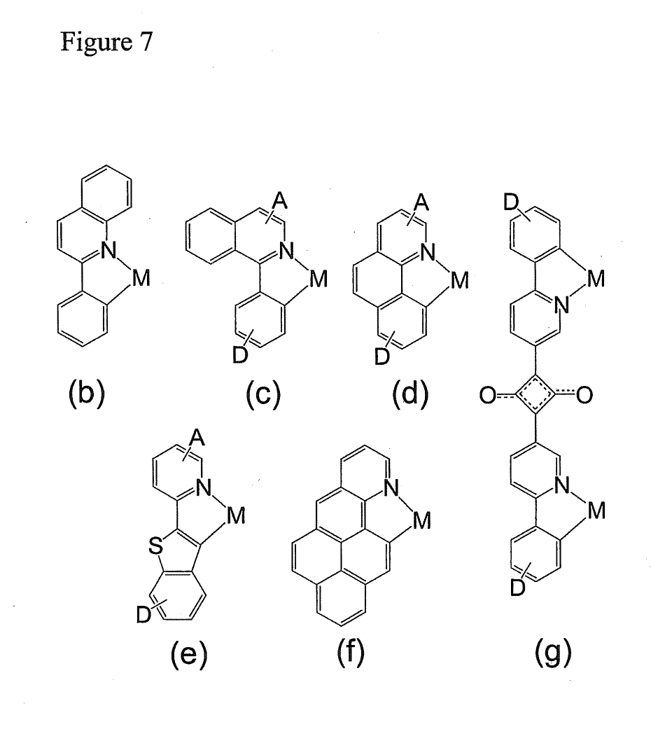

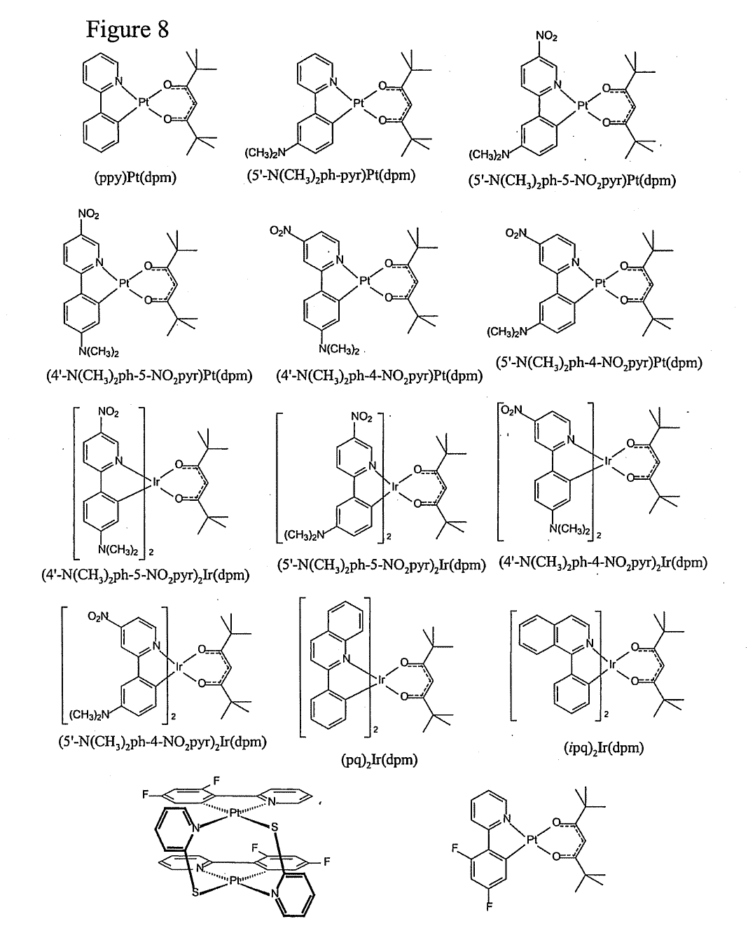

Several approaches may be used to red shifting the absorption bands into the near-IR part of the solar spectrum. The donor/acceptor substitution on ppy ligands shifted the λₘₐₓ for absorption to >700 nm for the Ir complexes, while the nonsubstituted analog (ppy₂Ir(dpm)) has its λₘₐₓ at 460 nm (with a comparable extinction). Alternatively, a comparable red shift may be achieved by extending the size of the π-system of the cyclometallated ligand. For example, the phenyl-quinoline derivative (pq₂Ir(dpm)), shows an absorption that is red shifted from ppy₂Ir(dpm) by 0.45 eV and an extinction coefficient that is nearly twice as large. The related structure in isoquinoline-based compound (ipq₂Ir(dpm)) has an absorption spectrum very similar to pq₂Ir(dpm). The dominant low energy absorption for these red shifted complexes is direct ground state to triplet excited state transitions. Electron donor or electron accepting substituents may be used to the further extended π-systems to shift the absorption energies to cover the range from 700 nm to 1.2 μm, since it is expected that the two affects are additive. The compounds shown in FIGS. 7 and 8 are markedly red shifted absorbance relative to their ppy analogs when unsubstituted (no electron donor nor electron accepting substituents).

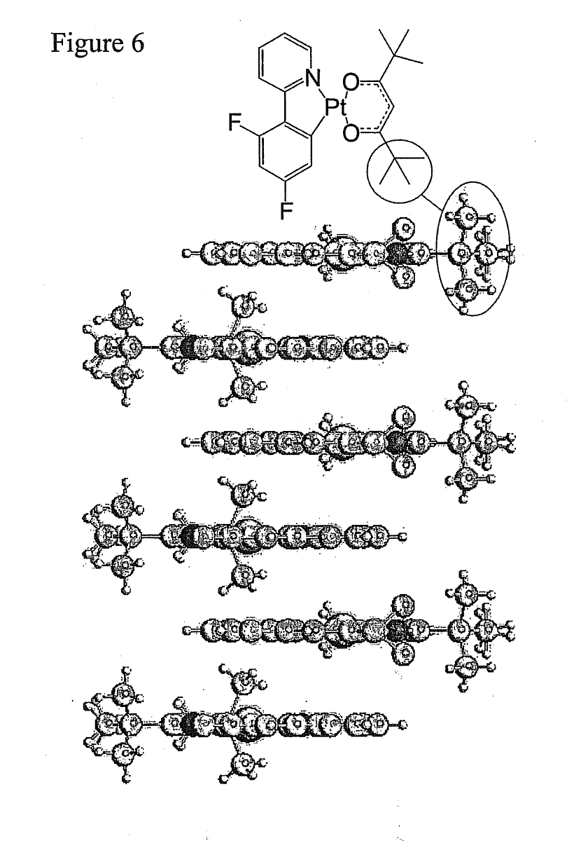

Square planar organometallic Pt complexes have been studied extensively in white OLEDs. The Pt complexes may form a mixture of monomer and excimer-like emitters. The formation of an excimer in the PV thin film may be problematic, as nearly a full volt is lost in the decrease of the excited state energy going from the monomer to the excimer. However, square-planar complexes may be designed which do not form excimers in the solid state by preventing the close approach of the central metal atoms. In every case where we have seen an excimer emission from crystals of square planar organometallic Pt complexes, the Pt atoms are within 3.8 Å of each other. Close approach of the π systems of the ligands (without a short Pt—Pt interaction) is not sufficient to promote excimer formation. In a preferred embodiment, sufficiently bulky ancillary ligands are used in order to prevent the Pt—Pt interaction. A preferred ancillary ligand is the dpm ligand used in the complexes of FIGS. 2-5. The dpm ligand is bulky enough to prevent any direct Pt—Pt interaction, but does not prevent the association of the π systems. This is shown in FIG. 6 for (F₂ ppy)Pt(dpm). These complexes crystallize in infinite π stacks, with the dpm groups on the periphery. Only monomer absorption and emission are observed for this complex. We expect that vapor deposited thin films of this material consist of nanoscale aggregates of these π stacks. This sort of packing arrangement is ideal for both exciton and carrier conduction. By substitution of the F₂ ppy ligand with donor and acceptor groups, the absorption energies may be shifted to the red-near IR part of the spectrum, as described above. Neither excimer emission nor the π-stacked chain structures are observed for the Ir complexes. The octahedral structures of the tris-chelates prevents strong π stacking.

Thus, in a preferred embodiment of the invention, compounds of the Formula IV and Formula V employ an ancillary ligand that has sufficient steric bulk to prevent the central metals from coming within about 3.8 Å of each other. In one embodiment, the ancillary ligand may be substituted with one or more bulky groups, such as alkyl groups. For example, an acac ancillary ligand may be substituted with multiple methyl groups as depicted below:

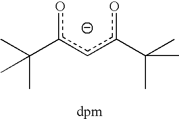

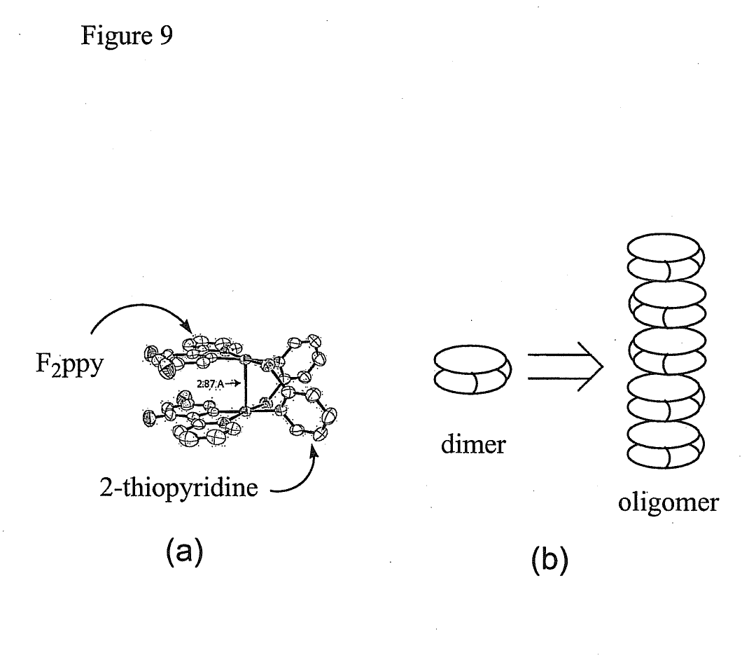

In another embodiment of the invention, physical dimers of the square planar complexes (e.g. FIG. 9) may be used as the cyclometallated organometallic compounds. The square planar dimer compounds may be selected from those taught in U.S. patent Ser. No. 10/404,785, filed Apr. 1, 2003, which is incorporated herein by reference in its entirety.

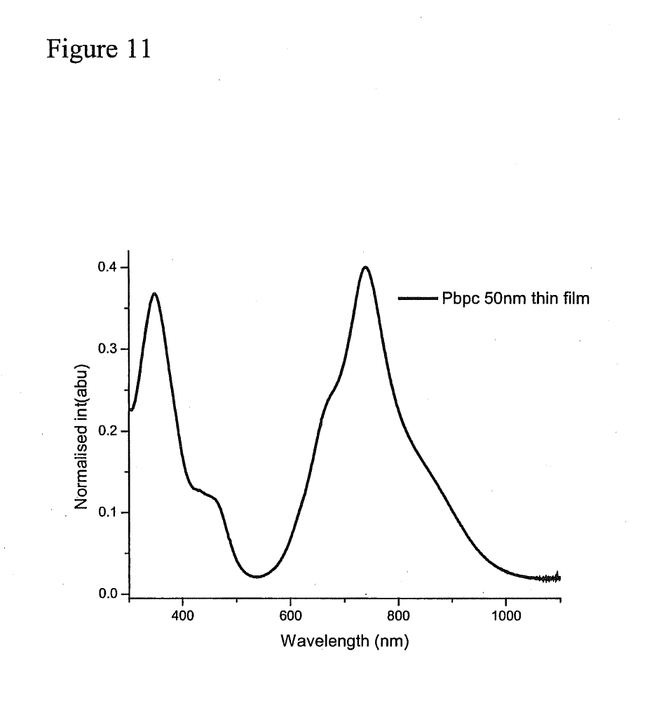

The lowest energy absorption band for the dimer complex, FPtblue is red shifted by 0.7 eV from the monomer (FPt) (λₘₐₓ=510 nm and 400 nm, respectively), This dimerization can be used to red shift the absorbance. Of particular interest here is the infinite chain complexes that the dimeric materials may materials form. It has been known of many years that dimers of this type will assemble in the solid state into aggregates, with markedly red shifted spectra (FIG. 11). They have been named the “platinum blue” complexes, due the deep blue color that develops on oligomerization. The Pt complex of FIG. 11 has the same CAN ligand as FPT (i.e. 4,6-F₂ ppy) and a bezamide bridging ligand. In dilute solution the complex is an orange color. On standing the complexes oligomerize, leading to the intense band in the near-IR shown in FIG. 11.

The organic layers may be fabricated using vacuum deposition, spin coating, organic vapor-phase deposition, inkjet printing and other methods known in the art.

The active region comprising a cyclometallated organometallic compound may be incorporated into an organic photosensitive optoelectronic device comprised of multiple subcells electrically connected in series produces a higher voltage device, as described in U.S. Pat. No. 6,657,378, incorporated herein by reference in its entirety. The donor-material and acceptor-material which provide the heterojunctions for the subcells may be the same for the various subcells or the donor- and acceptor materials may be different for the subcells of a particular device. The individual subcells of the stacked devices may be separated by an electron-hole recombination zone. The cyclometallated organometallic compounds as disclosed herein may be used as the donor or acceptor layer in one or more of the subcells.

The organic photosensitive optoelectronic devices of the present invention may function as a PV or solar cell, photodetector or photoconductor. Whenever the organic photosensitive optoelectronic devices of the present invention function as solar cells, the materials used in the photoconductive organic layers and the thicknesses thereof may be selected, for example, to optimize the external quantum efficiency of the device. Whenever the organic photosensitive optoelectronic devices of the present invention function as photodetectors or photoconductors, the materials used in the photoconductive organic layers and the thicknesses thereof may be selected, for example, to maximize the sensitivity of the device to desired spectral regions.

This result may be achieved by considering several guidelines that may be used in the selection of layer thicknesses. It is desirable for the exciton diffusion length, L_{D}, to be greater than or comparable to the layer thickness, L, since it is believed that most exciton dissociation will occur at an interface. If L_{D} is less than L, then many excitons may recombine before dissociation. It is further desirable for the total photoconductive layer thickness to be of the order of the electromagnetic radiation absorption length, l/α (where α is the absorption coefficient), so that nearly all of the radiation incident on the solar cell is absorbed to produce excitons. Furthermore, the photoconductive layer thickness should be as thin as possible to avoid excess series resistance due to the high bulk resistivity of organic semiconductors.

Accordingly, these competing guidelines inherently require tradeoffs to be made in selecting the thickness of the photoconductive organic layers of a photosensitive optoelectronic cell. Thus, on the one hand, a thickness that is comparable or larger than the absorption length is desirable (for a single cell device) in order to absorb the maximum amount of incident radiation. On the other hand, as the photoconductive layer thickness increases, two undesirable effects are increased. One is that due to the high series resistance of organic semiconductors, an increased organic layer thickness increases device resistance and reduces efficiency. Another undesirable effect is that increasing the photoconductive layer thickness increases the likelihood that excitons will be generated far from the effective field at a charge-separating interface, resulting in enhanced probability of geminate recombination and, again, reduced efficiency. Therefore, a device configuration is desirable which balances between these competing effects in a manner that produces a high quantum efficiency for the overall device.

The organic photosensitive optoelectronic devices of the present invention may function as photodetectors. In this embodiment, the device may be a multilayer organic device, for example as described in U.S. application Ser. No. 10/723,953, filed Nov. 26, 2003, incorporated herein by reference in its entirety. In this case an external electric field is generally applied to facilitate extraction of the separated charges.

A concentrator configuration can be employed to increase the efficiency of the organic photosensitive optoelectronic device, where photons are forced to make multiple passes through the thin absorbing regions. U.S. Pat. Nos. 6,333,458 and 6,440,769, incorporated herein by reference in their entirety, addresses this issue by using structural designs that enhance the photoconversion efficiency of photosensitive optoelectronic devices by optimizing the optical geometry for high absorption and for use with optical concentrators that increase collection efficiency. Such geometries for photosensitive devices substantially increase the optical path through the material by trapping the incident radiation within a reflective cavity or waveguiding structure, and thereby recycling light by multiple reflection through the thin film of photoconductive material. The geometries disclosed in U.S. Pat. Nos. 6,333,458 and 6,440,769 therefore enhance the external quantum efficiency of the devices without causing substantial increase in bulk resistance. Included in the geometry of such devices is a first reflective layer; a transparent insulating layer which should be longer than the optical coherence length of the incident light in all dimensions to prevent optical microcavity interference effects; a transparent first electrode layer adjacent the transparent insulating layer; a photosensitive heterostructure adjacent the transparent electrode; and a second electrode which is also reflective.

U.S. Pat. Nos. 6,333,458 and 6,440,769 also disclose an aperture in either one of the reflecting surfaces or an external side face of the waveguiding device for coupling to an optical concentrator, such as a Winston collector, to increase the amount of electromagnetic radiation efficiently collected and delivered to the cavity containing the photoconductive material. Exemplary non-imaging concentrators include a conical concentrator, such as a truncated paraboloid, and a trough-shaped concentrator. With respect to the conical shape, the device collects radiation entering the circular entrance opening of diameter d₁ within ±θₘₐₓ (the half angle of acceptance) and directs the radiation to the smaller exit opening of diameter d₂ with negligible losses and can approach the so-called thermodynamic limit. This limit is the maximum permissible concentration for a given angular field of view. Conical concentrators provide higher concentration ratios than trough-shaped concentrators but require diurnal solar tracking due to the smaller acceptance angle. (After High Collection Nonimaging Optics by W. T. Welford and R. Winston, (hereinafter “Welford and Winston”) pp. 172-175, Academic Press, 1989, incorporated herein by reference).

The term “halo” or “halogen” as used herein includes fluorine, chlorine, bromine and iodine.

The term “alkyl” as used herein contemplates both straight and branched chain alkyl radicals. Preferred alkyl groups are those containing from one to fifteen carbon atoms and includes methyl, ethyl, propyl, isopropyl, butyl, isobutyl, tert-butyl, and the like. Additionally, the alkyl group may be optionally substituted with one or more substituents selected from halo, CN, CO₂R, C(O)R, NR₂, cyclic-amino, NO₂, and OR, in which R is alkyl, aralkyl, aryl and heteroaryl.

The term “cycloalkyl” as used herein contemplates cyclic alkyl radicals. Preferred cycloalkyl groups are those containing 3 to 7 carbon atoms and includes cyclopropyl, cyclopentyl, cyclohexyl, and the like. Additionally, the cycloalkyl group may be optionally substituted with one or more substituents selected from halo, CN, CO₂R, C(O)R, NR₂, cyclic-amino, NO₂, and OR.

The term “alkenyl” as used herein contemplates both straight and branched chain alkene radicals. Preferred alkenyl groups are those containing two to fifteen carbon atoms. Additionally, the alkenyl group may be optionally substituted with one or more substituents selected from halo, CN, CO₂R, C(O)R, NR₂, cyclic-amino, NO₂, and OR.

The term “alkynyl” as used herein contemplates both straight and branched chain alkyne radicals. Preferred alkyl groups are those containing two to fifteen carbon atoms. Additionally, the alkynyl group may be optionally substituted with one or more substituents selected from halo, CN, CO₂R, C(O)R, NR₂, cyclic-amino, NO₂, and OR.

The term “aralkyl” as used herein contemplates an alkyl group which has as a substituent an aromatic group. Additionally, the aralkyl group may be optionally substituted on the aryl with one or more substituents selected from halo, CN, CO₂R, C(O)R, NR₂, cyclic-amino, NO₂, and OR.

The term “heterocyclic group” as used herein contemplates non-aromatic cyclic radicals. Preferred heterocyclic groups are those containing 5 or 6 ring atoms which includes at least one hetero atom, and includes cyclic amines such as morpholino, piperidino, pyrrolidino, and the like, and cyclic ethers, such as tetrahydrofuran, tetrahydropyran, and the like.

The term “aryl” or “aromatic group” as used herein contemplates single-ring aromatic groups (for example, phenyl, pyridyl, pyrazole, etc.) and polycyclic ring systems (naphthyl, quinoline, etc.). The polycyclic rings may have two or more rings in which two atoms are common to two adjoining rings (the rings are “fused”) wherein at least one of the rings is aromatic, e.g., the other rings can be cycloalkyls, cycloalkenyls, aryl, heterocycles and/or heteroaryls.

The term “heteroaryl” as used herein contemplates single-ring hetero-aromatic groups that may include from one to three heteroatoms, for example, pyrrole, furan, thiophene, imidazole, oxazole, thiazole, triazole, pyrazole, pyridine, pyrazine and pyrimidine, and the like. The term heteroaryl also includes polycyclic hetero-aromatic systems having two or more rings in which two atoms are common to two adjoining rings (the rings are “fused”) wherein at least one of the rings is a heteroaryl, e.g., the other rings can be cycloalkyls, cycloalkenyls, aryl, heterocycles and/or heteroaryls.

Devices have been constructed and example data recorded for exemplary embodiments of the present invention. The following examples of the invention are illustrative and not limiting of the invention.

### EXAMPLES

### Example 1

### Synthesis of 2-phenylpyridines

The donor-acceptor 2-phenylpyridine ligands precursor were prepared by Suzuki coupling of either 3- or 4-dimethylaminophenylboronic acid (Frontier Chemical) with either 2-bromo-4-nitropyridine or 2-bromo-5-nitropyridine (Aldrich) in 1,2-dimethoxyethane using a Pd(OAc)₂/PPh₃ catalyst and K₂CO₃ base as described in Synlett, 1999, 1, 45-48.

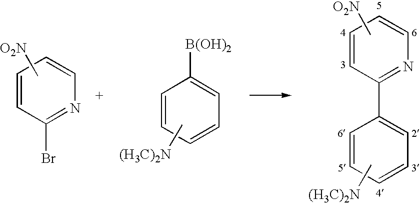

(A): 4′-N(CH₃)₂ph-5-NO₂pyr, 2-(4′-dimethylaminophenyl)-5-nitropyridine. ¹H NMR (250 MHz, CDCl₃), ppm: 9.38 (dd, 1H, J=2.7, 0.7 Hz), 8.38 (dd, 1H, J=9.2, 2.7 Hz), 8.01 (ddd, 2H, J=9.2, 3.1, 2.0 Hz), 7.73 (dd, 1H, J=9.2, 0.7 Hz), 6.76 (ddd, 2H, J=8.9, 3.1, 2.0 Hz), 3.06 (s, 6H). Anal. for C₁₃H₁₃N₃O₂: found C, 58.54; H, 4.71; N, 14.28. calcd C, 64.19; H, 5.39; N, 17.27.

(B): 4′-N(CH₃)₂ph-4-NO₂pyr, 2-(4′-dimethylaminophenyl)-4-nitropyridine. ¹H NMR (250 MHz, CDCl₃), ppm: 8.82 (dd, 1H, J=5.4, 0.7 Hz), 8.31 (dd, 1H, J=2.1, 0.7 Hz), 7.98 (ddd, 2H, J=9.2, 3.1, 2.0 Hz), 7.73 (dd, 1H, J=5.4, 2.1 Hz), 6.78 (ddd, 2H, J=8.9, 3.1, 2.0 Hz), 3.04 (s, 6H). Anal. for C₁₃H₁₃N₃O₂: found C, 63.85; H, 5.26; N, 16.84. calcd C, 64.19; H, 5.39; N, 17.27.

(C): 3′-N(CH₃)₂ph-5-NO₂pyr, 2-(3′-dimethylaminophenyl)-5-nitropyridine. ¹H NMR (250 MHz, CDCl₃), ppm: 9.47 (dd, 1H, J=2.7, 0.7 Hz), 8.49 (dd, 1H, J=8.5, 2.7 Hz), 7.89 (d, 1H, J=8.8 Hz), 7.04 (m, 3H), 6.89 (s, 1H Hz), 3.04 (s, 6H). Anal. for C₁₃H₁₃N₃O₂: found C, 63.37; H, 4.80; N, 16.65. calcd C, 64.19; H, 5.39; N, 17.27.

(D): 3′-N(CH₃)₂ph-4-NO₂pyr, 2-(3′-dimethylaminophenyl)-4-nitropyridine. ¹H NMR (250 MHz, CDCl₃), ppm: 8.93 (dd, 1H, J=5.1, 0.7 Hz), 8.41 (dd, 1H, J=2.1, 0.7 Hz), 7.90 (dd, 1H, J=5.5, 5.1 Hz), 7.37 (m, 3H), 6.86 (ddd, 1H, J=7.2, 2.1, 2.1 Hz), 3.04 (s, 6H). Anal. for C₁₃H₁₃N₃O₂: found C, 62.85; H, 2.87; N, 15.96. calcd C, 64.19; H, 5.39; N, 17.27.

### Example 2

### Synthesis of [(donor-acceptor 2-(phenyl)pyridinato-N,C^{2′})₂PtCl]₂ Complexes

All procedures involving K₂PtCl₄ or any other Pt(II) species were carried out in inert gas atmosphere in spite of the air stability of the compounds, the main concern being their oxidative stability and stability of intermediate complexes at high temperatures used in the reactions. The donor-acceptor cyclometallated Pt(II) μ-dichloro bridged dimers of a general formula (C\textcircled{}N)Pt(μ-Cl)₂Pt(C\textcircled{}N) were synthesized by heating a mixture of K₂PtCl₄ with 2-2.5 equivalents of donor-acceptor 2-phenylpyridine in a 3:1 mixture of 2-ethoxyethanol (Aldrich) and water to 80° C. for 16 hours. The product was isolated by addition of water followed by filtration and methanol wash.

### Example 3

### General Synthesis of Platinum(II) (donor-acceptor 2-(phenyl)pyridinato-N,C^{2′})(2,2,6,6-tetramethyl-3,5-heptanedionato-O,O) Complexes

The [(donor-acceptor 2-(phenyl)pyridinato-N,C^{2′})PtCl]₂ complexes were treated with 3 eq of 2,2,6,6-tetramethyl-3,5-heptanedione (dpmH) and 10 eq of Na₂CO₃ in 2-ethoxyethanol at 80° C. under inert gas atmosphere for 16 hours. After cooling to room temperature, the solvent was removed under reduced pressure and the crude product was washed with methanol. The crude product was flash chromatographed on a silica column with dichloromethane to yield ca. 25-35% of the pure. (C\textcircled{}N)Pt(dpm) after solvent evaporation and drying.

[Pt(A)]: (4′-N(CH₃)₂ph-5-NO₂pyr)Pt(dpm), platinum(II) (2-(4′-dimethylaminophenyl)-5-nitropyridinato-N,C^{2′})(2,2,6,6-tetramethyl-3,5-heptanedionato-O,O). ¹H NMR (250 MHz, CDCl₃), ppm: 9.78 (d, 1H, J=2.4 Hz), 8.30 (dd, 1H, J=9.2, 2.4 Hz), 7.34 (dd, 2H, J=8.9, 2.4 Hz), 6.94 (d, 1H, J=2.7 Hz), 6.49 (dd, 1H, J=8.9, 2.7 Hz), 5.81 (s, 1H), 3.12 (s, 6H), 1.29 (s, 9H), 1.26 (s, 9H). Anal. for C₂₄H₃₁N₃O₄Pt: found C, 46.18; H, 4.55; N, 6.49. calcd C, 46.45; H, 5.03; N, 6.77.

[Pt(B)]: (4′-N(CH₃)₂ph-4-NO₂pyr)Pt(dpm), platinum(II) (2-(4′-dimethylaminophenyl)-4-nitropyridinato-N,C^{2′})(2,2,6,6-tetramethyl-3,5-heptanedionato-O,O). ¹H NMR (250 MHz, CDCl₃), ppm: 9.09 (d, 1H, J=6.5 Hz), 8.02 (d, 1H, J=2.4 Hz), 7.49 (dd, 1H, J=6.1, 2.4 Hz), 7.37 (d, 1H, J=8.9 Hz), 6.99 (d, 1H, J=2.7 Hz), 6.52 (d, 1H, J=8.9 Hz), 5.80 (s, 1H), 3.10 (s, 6H), 1.26 (s, 9H), 1.25 (s, 9H). Anal. for C₂₄H₃₁N₃O₄Pt: found C, 46.23; H, 4.64; N, 6.58. calcd C, 46.45; H, 5.03; N, 6.77.

[Pt(C)]: (5′-N(CH₃)₂ph-5-NO₂pyr)Pt(dpm), platinum(II) (2-(5′-dimethylaminophenyl)-5-nitropyridinato-N,C^{2′})(2,2,6,6-tetramethyl-3,5-heptanedionato-O,O). ¹H NMR (250 MHz, CDCl₃), ppm: 9.97 (d, 1H, J=2.4 Hz), 8.48 (dd, 1H, J=8.9, 2.4 Hz), 7.63 (d, 1H, J=8.9 Hz), 7.52 (d, 1H, J=8.5 Hz), 6.97 (dd, 1H, J=8.9, 2.7 Hz), 6.86 (d, 1H, J=2.7 Hz), 5.81 (s, 1H), 2.95 (s, 6H), 1.30 (s, 9H), 1.26 (s, 9H). Anal. for C₂₄H₃₁N₃O₄Pt: found C, 45.72; H, 3.04; N, 6.10. calcd C, 46.45; H, 5.03; N, 6.77.

[Pt(D)]: (5′-N(CH₃)₂ph-4-NO₂pyr)Pt(dpm), platinum(II) (2-(5′-dimethylaminophenyl)-4-nitropyridinato-N,C^{2′})(2,2,6,6-tetramethyl-3,5-heptanedionato-O,O). ¹H NMR (250 MHz, CDCl₃), ppm: 9.32 (d, 1H, J=6.5 Hz), 8.22 (d, 1H, J=2.0 Hz), 7.73 (dd, 1H, J=6.5, 2.4 Hz), 7.55 (d, 1H, J=8.5 Hz), 6.99 (m, 2H), 5.80 (s, 1H), 2.98 (s, 6H), 1.26 (s, 9H), 1.25 (s, 9H). Anal. for C₂₄H₃₁N₃O₄Pt: found C, 46.08; H, 4.44; N, 6.45. calcd C, 46.45; H, 5.03; N, 6.77.

### Example 4

### Synthesis of [(donor-acceptor 2-(phenyl)pyridinato-N,C^{2′})₂IrCl]₂ Complexes

All procedures involving IrCl₃.H₂O or any other Ir(III) species were carried out in inert gas atmosphere in spite of the air stability of the compounds, the main concern being their oxidative stability and stability of intermediate complexes at high temperatures used in the reactions. The donor-acceptor cyclometalated Ir(III) μ-dichloro bridged dimers of a general formula (C\textcircled{}N)₂Ir(μ-Cl)₂Ir(C\textcircled{}N)₂ were synthesized by heating a mixture of IrCl₃.H₂O with 4 eq. of donor-acceptor 2-phenylpyridine in 2-ethoxyethanol at 120° C. for 16 hr. The product was isolated by addition of water followed by filtration and methanol wash. Yield 90%.

### Example 5

### General Synthesis of Iridium(III) bis(2-(donor-acceptor 2-(phenyl)pyridinato-N,C^{2′})(2,2,6,6-tetramethyl-3,5-heptanedionato-O,O) Complexes

The [(donor-acceptor 2-(phenyl)pyridinato-N,C^{2′})₂IrCl]₂ complexes were treated with 5 eq of 2,2,6,6-tetramethyl-3,5-heptanedione (dpmH) and 10 eq of Na₂CO₃ in refluxing 1,2-dichloroethane under inert gas atmosphere for 16 hours. After cooling down to room temperature, the solvent was removed under reduced pressure and the crude product was washed with methanol. The crude product was flash chromatographed using a silica:dichloromethane column to yield ca. 50% (C\textcircled{}N)₂Ir(dpm) after solvent evaporation and drying.

[Ir(A)₂]: (4′-N(CH₃)₂ph-5-NO₂pyr)₂Ir(dpm), iridium(III) bis[(2-(4′-dimethylaminophenyl)-5-nitropyridinato-N,C^{2′})](2,2,6,6-tetramethyl-3,5-heptanedionato-O,O). ¹H NMR (250 MHz, CDCl₃), ppm: 9.10 (d, 2H, J=2.4 Hz), 8.21 (dd, 2H, J=9.2, 2.4 Hz), 8.02 (d, 2H, J=8.8 Hz), 6.76 (d, 2H, J=8.8 Hz), 6.31 (dd, 2H, J=8.8, 2.7 Hz), 5.57 (d, 2H, J=2.7 Hz), 5.53 (s, 1H), 2.80 (s, 12H), 0.97 (s, 18H).

[Ir(B)₂]: (4-N(CH₃)₂ph-4-NO₂pyr)₂Ir(dpm), iridium(III) bis[(2-(4′-dimethylaminophenyl)-4-nitropyridinato-N,C^{2′})](2,2,6,6-tetramethyl-3,5-heptanedionato-O,O). ¹H NMR (250 MHz, CDCl₃), ppm: 8.45 (d, 2H, J=6.1 Hz), 8.25 (d, 2H, J=2.4 Hz), 7.49 (d, 2H, J=8.8 Hz), 7.44 (dd, 2H, J=6.5, 2.4 Hz), 6.30 (dd, 2H, J=8.8, 2.4 Hz), 5.52 (d, 2H, J=2.4 Hz), 5.48 (s, 1H), 2.76 (s, 12H), 0.90 (s, 18H).

[Ir(C)₂]: (5-N(CH₃)₂ph-5-NO₂pyr)₂Ir(dpm), iridium(III) bis[(2-(5′-dimethylaminophenyl)-5-nitropyridinato-N,C^{2′})](2,2,6,6-tetramethyl-3,5-heptanedionato-O,O). ¹H NMR (250 MHz, CDCl₃), ppm: 9.23 (d, 2H, J=2.3 Hz), 8.37 (dd, 2H, J=9.2, 2.4 Hz), 7.87 (d, 2H, J=9.2 Hz), 7.02 (d, 2H, J=2.7 Hz), 6.49 (dd, 2H, J=8.5, 2.7 Hz), 6.21 (d, 2H, J=8.5 Hz), 5.55 (s, 1H), 2.84 (s, 12H), 0.95 (s, 18H).

[Ir(D)₂]: (5′-N(CH₃)₂ph-4-NO₂pyr)₂Ir(dpm), iridium(III) bis[(2-(5′-dimethylaminophenyl)-4-nitropyridinato-N,C^{2′})](2,2,6,6-tetramethyl-3,5-heptanedionato-O,O). ¹H NMR (250 MHz, CDCl₃), ppm: 8.62 (d, 2H, J=6.5 Hz), 8.46 (d, 2H, J=2.4 Hz), 7.68 (dd, 2H, J=6.4, 2.3 Hz), 7.07 (d, 2H, J=2.7 Hz), 6.47 (dd, 2H, J=8.4, 2.7 Hz), 6.11 (d, 2H, J=8.4 Hz), 5.50 (s, 1H), 2.86 (s, 12H), 0.89 (s, 18H).

The electrochemical properties of the ligands and the complexes were characterized by cyclic voltammetry (CV) and differential pulsed voltammetry (DPV). These measurements were preformed using an EG&G potentiostat/galvanostat model 283. Anhydrous 1,2-dichloroethane from Aldrich Chemical Co. was used as the solvent under a nitrogen atmosphere and 0.1M tetra(n-butyl)ammonium hexafluorophosphate was used as the supporting electrolyte. A Ag wire was used as the pseudoreference electrode and a Pt wire was used as the counter electrode. The working electrode was glassy carbon. The redox potentials are based on values measured from differential pulsed voltammetry and are reported relative to a ferrocene/ferrocenium (Cp₂Fe/Cp₂Fe⁺) redox couple used as an internal reference. Reversibility was determined by measuring the areas of the anodic and cathodic peaks from cyclic voltammetry. All the ligands and complexes showed reversible reduction between −1.17 and −1.55V and reversible, quasi-reversible or irreversible oxidation between 0.16 and 0.56V (Table 1).

TABLE 1
Redox Properties of Ligands and Pt-Complexes

| Complexes & Ligands | E_{1/2}^{red} (V)^{a} | E_{1/2}^{ox} (V)^{a} | E_{1/2} gap (V) | E_{1/2} gap (nm) |
|---|---|---|---|---|
| 4′-N(CH₃)₂ph-5-NO₂pyr | −1.55 | 0.56 | 2.11 | 588 |
| (4′-N(CH₃)₂ph-5-NO₂pyr)Pt(dpm) | −1.44 | 0.46^{c} | 1.90 | 653 |
| 4′-N(CH₃)₂ph-4-NO₂pyr | −1.41 | 0.53 | 1.94 | 639 |
| (4′-N(CH₃)₂ph-4-NO₂pyr)Pt(dpm) | −1.24 | 0.42^{c} | 1.66 | 747 |
| 5′-N(CH₃)₂ph-5-NO₂pyr | −1.49 | 0.51^{b} | 2.00 | 620 |
| (5′-N(CH₃)₂ph-5-NO₂pyr)Pt(dpm) | −1.34 | 0.18 | 1.52 | 816 |
| 5′-N(CH₃)₂ph-4-NO₂pyr | −1.36 | 0.47^{b} | 1.83 | 678 |
| (5′-N(CH₃)₂ph-4-NO₂pyr)Pt(dpm) | −1.17 | 0.16 | 1.33 | 932 |

^{a}Reduction and oxidation measurements were carried out in 1,2-dichloroethane solution; values are reported relative to Cp₂Fe/Cp₂Fe⁺.
^{b}Irreversible.
^{c}Quasi-reversible.

As can be seen from the data in Table 1, ligand 4′-N(CH₃)₂ph-5-NO₂pyr was the hardest to oxidize and the easiest to reduce, while ligand 5′-N(CH₃)₂ph-4-NO₂pyr was the easiest to oxidize and the hardest to reduce. It is expected that the oxidation of the ligands is localized on the phenyl ring and the reduction on the pyridine ring. The amino group in the 4′ position and the nitro group in the 5 position had a significant contribution in the increase of the oxidation and reduction potentials respectively compared to the other positions. This may be due to the increased conjugation of the ligand, which results in a better communication between the pyridine and the phenyl rings.

Therefore, when an electron localized on the phenyl ring is removed the electron donation from the nitro group on the pyridine ring makes it more difficult to oxidize. The same is true for reduction—addition of an electron to the pyridine ring which has electron donation from the dimethylamino group on the phenyl ring increases the reduction potential.

The complexes with ligands that had reversible oxidation (4′-N(CH₃)₂ph-5-NO₂pyr, 4′-N(CH₃)₂ph-4-NO₂pyr) had quasi-reversible oxidation and the complexes with the ligands that showed irreversible oxidation (5′-N(CH₃)₂ph-5-NO₂pyr, 5′-N(CH₃)₂ph-4-NO₂pyr) had reversible oxidation. Due to the presence of the platinum metal the complexes compared to the respective ligands were easier to oxidize and harder to reduce. For the complexes, reduction is considered to be localized on the ligand while the oxidation is believed to be centered on the metal. This is consistent with previous DFT calculations for ppyPt(dpm) with LUMO electron density localized on the ligand and a larger HOMO electron density on the metal.

In the Pt complexes in Table 1, we see a decrease in the electron density localized on the metal compared to ppyPt(dpm). The presence of the platinum metal strongly perturbs the ligand based excited states. It lowers the energy gap between the ligand and its respective complex by inducing a quinoidal character to the ligand through the metal. For example, although the complex with the two ligand substituents in the para position to the metal ((5′-N(CH₃)₂ph-4-NO₂pyr)Pt(dpm)) had the smallest HOMO-LUMO energy gap, it had the largest energy difference between the complex and ligand energies due to an additional conjugation through the metal. On the other hand (4′-N(CH₃)₂ph-5-NO₂pyr)Pt(dpm), which was the least conjugated of the complexes, had the smallest energy difference between the ligand and the complex.

Although the HOMO-LUMO gap for the ligands was relatively the same, the gap for the complexes had a larger difference. The largest HOMO-LUMO energy gap was observed for (4′-N(CH₃)₂ph-5-NO₂pyr)Pt(dpm) and the smallest for (5′-N(CH₃)₂ph-4-NO₂pyr)Pt(dpm) and their respective ligands as was predicted due to additional conjugation through the metal.

The UV-vis spectra of the ligands and complexes were recorded in dichloromethane and hexane solutions at room temperature using an Aviv model 14DS spectrophotometer (FIGS. 8 and 9). The ligands were less soluble in hexanes. The absorption spectra of the complexes in hexanes was highly structured.

The low energy transitions of the complexes are assigned as metal-to-ligand-charge-transfer (MLCT) transitions, and the more intense higher energy absorption bands are assigned to π-π* ligand-centered (LC) transition. These bands are not very solvatochromic but they are shifted in the complexes due to the perturbations from the metal.

The peak due to the π-π* transition of (4′-N(CH₃)₂ph-5-NO₂pyr)Pt(dpm) in DCM was observed at 520 nm (ε=2.8×10⁴ M⁻¹ cm⁻¹), which was bathochromic shifted in comparison with that of 4′-N(CH₃)₂ph-5-NO₂pyr, 434 nm (ε=4.8×10³ M⁻¹ cm⁻¹). This trend was observed for all the ligands and their respective platinum complexes. Free ligands displayed a more positive solvatochromism compared to their Pt-complexes. Among the ligands 4′-N(CH₃)₂ph-5-NO₂pyr and 5′-N(CH₃)₂ph-5-NO₂pyr were more solvatochromic. This behaviour is consistent with the structural characteristics of the ligands due to the additional π-conjugation through the amino group in the 5 position and the nitro group in the 4′ position.

(4′-N(CH₃)₂ph-5-NO₂pyr)Pt(dpm) had a large extinction coefficient at 520 nm. The other complexes had extinction coefficients approximately 5 times less than that of (4′-N(CH₃)₂ph-5-NO₂pyr)Pt(dpm) at this wavelength. The high oscillator strength of transition of (4′-N(CH₃)₂ph-5-NO₂pyr)Pt(dpm) at low energy can be attributed to the increased communication between the phenyl and the pyridine rings. The other complexes do not have such good communication through the rings. The emission spectra were not observed for either the ligands or the complexes. The complexes may have an emission in the far red/infra red region which lies outside the range of our detection equipment.

Although the present invention is described with respect to particular examples and preferred embodiments, it is understood that the present invention is not limited to these examples and embodiments. The present invention as claimed may therefore include variations from the particular examples and preferred embodiments described herein, as will be apparent to one of skill in the art.

What is claimed is:

1. An organic photosensitive optoelectronic device comprising:
an anode;
an active region comprising a cyclometallated organometallic material; and
a cathode,
wherein the device produces a photogenerated current when illuminated with light.

2. The organic photosensitive optoelectronic device of claim 1, wherein the cyclometallated organometallic material comprises an Ir or Pt atom.

3. The organic photosensitive optoelectronic device of claim 1, wherein the device further comprises a blocking layer.

4. The organic photosensitive optoelectronic device of claim 1, wherein the cyclometallated organometallic material has the formula I 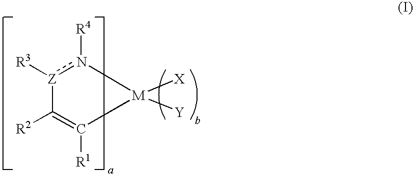
wherein
M is a transition metal having a molecular weight greater than 40;
Z is N or C,
the dotted line represents an optional double bond,
R¹, R², R³ and R⁴ are independently selected from H, alkyl, or aryl, and additionally or alternatively, one or more of R¹ and R², R² and R³, and R³ and R⁴ together from independently a 5 or 6-member cyclic group, wherein said cyclic group is cycloalkyl, cycloheteroalkyl, aryl or heteroaryl; and wherein said cyclic group is optionally substituted by one or more substituents Q;
each substituent Q is independently selected from the group consisting of alkyl, alkenyl, alkynyl, aralkyl, CN, CF₃, NR₂, NO₂, OR, halo, and aryl, and additionally, or alternatively, two Q groups on adjacent ring atoms form a fused 5- or 6-membered aromatic group;
each R is independently selected from H, alkyl, aralkyl, aryl and heteroaryl;
(X and Y), separately or in combination, are an ancillary ligand;
a is 1 to 3; and
b is 0 to 2;
with the proviso that the sum of a and b is 2 or 3.

5. The organic photosensitive optoelectronic device of claim 1, wherein the cyclometallated organometallic material has the formula 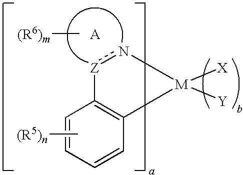
wherein
M is a transition metal having a molecular weight greater than 40;
ring A is an aromatic heterocyclic ring or a fused aromatic heterocyclic ring with at least one nitrogen atom that coordinates to the metal M;
Z is selected from carbon or nitrogen;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4;
m is 0 to 4;
a is 1 to 3; and
b is 0 to 2;
with the proviso that the sum of a and b is 2 or 3.

6. The organic photosensitive optoelectronic device of claim 5, wherein the cyclometallated organometallic material has the formula 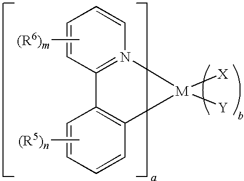
wherein
M is a transition metal having a molecular weight greater than 40;
ring A is an aromatic heterocyclic ring or a fused aromatic heterocyclic ring with at least one nitrogen atom that coordinates to the metal M;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4;
m is 0 to 4;
a is 1 to 3; and
b is 0 to 2;
with the proviso that the sum of a and b is 2 or 3.

7. The organic photosensitive optoelectronic device of claim 5, wherein the cyclometallated organometallic material has the formula IV 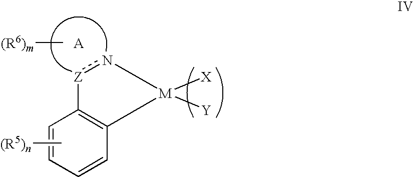
wherein
M is a transition metal having a molecular weight greater than 40;
ring A is an aromatic heterocyclic ring or a fused aromatic heterocyclic ring with at least one nitrogen atom that coordinates to the metal M;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

8. The organic photosensitive optoelectronic device of claim 7, wherein the cyclometallated organometallic material has the formula V 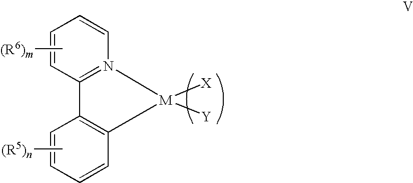
wherein
M is a transition metal having a molecular weight greater than 40;
each R⁵ is independently selected from the group consisting of alkyl, alkenyl, alkynyl, aralkyl, CN, CF₃, NR₂, NO₂, OR, halo, and aryl, and additionally, or alternatively, two R⁵ groups on adjacent ring atoms form a fused 5- or 6-membered aromatic group;
each R⁶ is independently selected from the group consisting of alkyl, alkenyl, alkynyl, aralkyl, CN, CF₃, NR₂, NO₂, OR, halo, and aryl, and additionally, or alternatively, two R⁶ groups on adjacent ring atoms form a fused 5- or 6-membered aromatic group;
each R is independently selected from H, alkyl, aralkyl, aryl and heteroaryl;
(X and Y), separately or in combination, are an ancillary ligand;
n is 0 to 4; and
m is 0 to 4.

9. The organic photosensitive optoelectronic device of claim 7, wherein M is Pt.

10. The organic photosensitive optoelectronic device of claim 7, wherein the cyclometallated organometallic material forms π-stacked chains.

11. The organic photosensitive optoelectronic device of claim 9, wherein the cyclometallated organometallic material has the formula

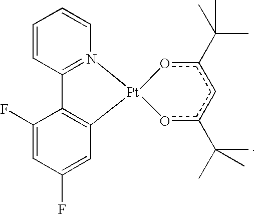

12. The organic photosensitive optoelectronic device of claim 1, wherein the cyclometallated organometallic material absorbs light in the red or near IR portion of the spectrum.

13. The organic photosensitive optoelectronic device of claim 1, wherein the device is a photovoltaic device.

14. The organic photosensitive optoelectronic device of claim 1, wherein the device is a photodetector.

15. The organic photosensitive optoelectronic device of claim 1, wherein the device is a photoconductor.

16. The organic photosensitive optoelectronic device of claim 1, wherein the device comprises multiple subcells in series.
